(19) United States
(12) Patent Application Publication
(10) Pub. No.: US 2026/0182128 A1
(43) Pub. Date: Jun. 25, 2026

(54) DISPLAY PANEL AND DISPLAY APPARATUS

(71) Applicant: BOE Technology Group Co., Ltd., Beijing (CN)

(72) Inventors: Wenxiu Zhu, Beijing (CN); Mingche Hsieh, Beijing (CN)

(73) Assignee: BOE Technology Group Co., Ltd., Beijing (CN)

(21) Appl. No.: 18/727,164

(22) PCT Filed: Sep. 22, 2023
(86) PCT No.: PCT/CN2023/120650

§ 371 Date: Jul. 8, 2024

(51) Int. Cl. H10H 29/855

(52) U.S. Cl. CPC H10H 29/8552

(57) ABSTRACT

A display panel is provided. The display panel includes a plurality of first pixels; a plurality of second pixels; a first black matrix; and a second black matrix. The first black matrix is at least partially present in regions having the plurality of first pixels and regions having the plurality of second pixels. The second black matrix is at least partially present in the regions having the plurality of second pixels, and at least partially absent in the regions having the plurality of first pixels.

### TECHNICAL FIELD

The present invention relates to display technology, more particularly, to a display panel and a display apparatus

### BACKGROUND

Display apparatuses such as mobile phones have been developed to provide many functions. A user may use a display apparatus to access various private information. For example, the user may use the display apparatus to access bank accounts, pay bills, carry out on-line purchases, and access various password-protected websites. Personal information of these types is private and is often subject to identity theft and invasion of privacy. Thus, in recent years, privacy protection has become a focus of research and development in display technology.

### SUMMARY

In one aspect, the present disclosure provides a display panel, comprising a plurality of first pixels; a plurality of second pixels; a first black matrix; and a second black matrix; wherein the first black matrix is at least partially present in regions having the plurality of first pixels and regions having the plurality of second pixels; and the second black matrix is at least partially present in the regions having the plurality of second pixels, and at least partially absent in the regions having the plurality of first pixels.

Optionally, the regions having the plurality of first pixels is substantially absent of the second black matrix; in the regions having the plurality of first pixels, an orthographic projection of the first black matrix on a base substrate is substantially non-overlapping with an orthographic projection of the second black matrix on the base substrate; and in the regions having the plurality of second pixels, the orthographic projection of the first black matrix on the base substrate at least partially overlaps with the orthographic projection of the second black matrix on the base substrate.

Optionally, the second black matrix comprises a plurality of bars; the display panel: comprises a plurality of slits; the plurality of bars and the plurality of slits are alternately arranged; two adjacent bars of the plurality of bars are spaced apart by a slit of the plurality of slits; and two adjacent slits of the plurality of slits are spaced apart by a bar of the plurality of bars.

Optionally, the display panel further comprises a pixel definition layer defining a plurality of first subpixel apertures in the regions having the plurality of first pixels and a plurality of second subpixel apertures in the regions having the plurality of second pixels; wherein, in the regions having the plurality of first pixels, a portion of the first black matrix between two adjacent subpixels has a first width along a plane intersecting the two adjacent subpixels and the portion of the first black matrix and perpendicular to a surface of the base substrate, a portion of the pixel definition layer between the same two adjacent subpixels has a second width along a plane intersecting the two adjacent subpixels and the portion of the pixel definition layer and perpendicular to the surface of the base substrate, the second width being greater than the first width; and in the regions having the plurality of second pixels, a portion of the first black matrix between two adjacent subpixels has a third width along a plane intersecting the two adjacent subpixels and the portion of the first black matrix and perpendicular to a surface of the base substrate, a portion of the pixel definition layer between the same two adjacent subpixels has a fifth width along a plane intersecting the two adjacent subpixels and the portion of the pixel definition layer and perpendicular to the surface of the base substrate, the third width being substantially the same as the fifth width.

Optionally, in the regions having the plurality of second pixels, a portion of the second black matrix between the same two adjacent subpixels has a fourth width along a plane intersecting the two adjacent subpixels and the portion of the second black matrix and perpendicular to the surface of the base substrate; and the fourth width is greater than the fifth width.

Optionally, in the regions having the plurality of second pixels, a portion of the second black matrix between the same two adjacent subpixels has a fourth width along a plane intersecting the two adjacent subpixels and the portion of the second black matrix and perpendicular to the surface of the base substrate; and the fourth width is substantially the same as the fifth width.

Optionally, the display panel comprises: a plurality of first apertures extending through the first black matrix; a plurality of second apertures extending through the first black matrix; and a plurality of third apertures extending through the second black matrix; the plurality of first apertures are configured to allow light emitted from a plurality of first light emitting elements in a plurality of first subpixels to transmit through; the plurality of second apertures are configured to allow light emitted from a plurality of second light emitting elements in a plurality of second subpixels to transmit through; and the plurality of third :apertures are configured to allow light emitted from a plurality of second light emitting elements in the plurality of second subpixels to transmit through; wherein, in the portion of the display panel having the plurality of second pixels, a second aperture of the plurality of second apertures configured to allow light emitted from a second light emitting element to transmit through has a first aperture width along a plane intersecting two adjacent second subpixels and perpendicular to a surface of the base substrate, and a third aperture of the plurality of third apertures configured to allow light emitted from a same second light emitting element to transmit through has a second aperture width along the plane intersecting the two adjacent second subpixels and perpendicular to the surface of the base substrate.

Optionally, the first aperture width is greater than the second aperture width.

Optionally, an orthographic projection of an edge of the second aperture on a base substrate substantially surrounds an orthographic projection of an edge of the third aperture on the base substrate.

Optionally, the first aperture width and the second aperture width are substantially the same.

Optionally, an orthographic projection of an edge of the second aperture on a base substrate and an orthographic projection of an edge of the third aperture on the base substrate substantially overlap with each other.

Optionally, in the regions having the plurality of second pixels, the display panel further comprises: an insulating layer spacing apart the first black matrix and the second black matrix; and a light control structure at least partially extending through the insulating layer; wherein the light control structure is connected to a portion of the first black matrix, and is connected to a portion of the second black matrix.

Optionally, the second black matrix comprises multiple sub-layers; two adjacent sub-layers of the multiple sub-layers are spaced apart by an insulating layer; and orthographic projections of the multiple sub-layers on a base substrate substantially overlap with each other.

Optionally, the display panel further comprises a lens layer comprising a plurality of lenses; wherein, in the regions having the plurality of second pixels, an orthographic projection of a respective lens of the plurality of lenses on the base substrate at least partially overlaps with an orthographic projection of a second light emitting element on the base substrate.

Optionally, the display panel comprises: a first overcoat layer; the plurality of lenses and the first black matrix on the first overcoat layer; a second overcoat layer on a side of the plurality of lenses and the first black matrix away from the first overcoat layer; and the second black matrix on a side of the second overcoat layer away from the plurality of lenses and the first black matrix.

Optionally, the display panel comprises: a first overcoat layer; the first black matrix on the first overcoat layer; a second overcoat layer on a side of the first black matrix away from the first overcoat layer; and the plurality of lenses and the second black matrix on a side of the second overcoat layer away from the first black matrix.

Optionally, the display panel comprises: a first overcoat layer; the first black matrix on the first overcoat layer; a second overcoat layer on a side of the first black matrix away from the first overcoat layer; and the second black matrix on a side of the second overcoat layer away from the first black matrix; a third overcoat layer on a side of the second black matrix away from the second overcoat layer; and the plurality of lenses on a side of the third overcoat layer away from the second black matrix.

Optionally, the display panel comprises a plurality of first pixel rows and a plurality of second pixel rows alternately arranged; two adjacent first pixel rows of the plurality of first pixel rows are spaced apart by an individual second pixel row of the plurality of second pixel rows; two adjacent second pixel rows of the plurality of second pixel rows are spaced apart by an individual first pixel row of the plurality of first pixel rows; a respective first pixel row of the plurality of first pixel rows comprises multiple pixels of the plurality of first pixels; a respective second pixel row of the plurality of second pixel rows comprises multiple second pixels of the plurality of second pixels; a respective first pixel of the plurality of first pixels comprises a first subpixel, a second subpixel, and a third subpixel; and a respective second pixel of the plurality of second pixels comprises multiple fourth subpixels, multiple fifth subpixels, and multiple sixth subpixels.

In another aspect, the present disclosure provides a display panel, comprising a plurality of first pixels; a plurality of second pixels; a first black matrix; and a second black matrix; wherein, in regions having the plurality of first pixels, an orthographic projection of the first black matrix on a base substrate is substantially non-overlapping with an orthographic projection of the second black matrix on the base substrate; and in regions having the plurality of second pixels, the orthographic projection of the first black matrix on the base substrate at least partially overlaps with the orthographic projection of the second black matrix on the base substrate.

In another aspect, the present disclosure provides a display apparatus, comprising the display panel described herein, and one or more integrated circuits connected to the display panel.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating a pixel arrangement in a display panel in some embodiments according to the present disclosure.

FIG. 2 illustrates the structure of a portion of a display panel in some embodiments according to the present disclosure.

FIG. 3 is a schematic diagram illustrating a pixel arrangement in a display panel in some embodiments according to the present disclosure.

FIG. 4 is a schematic diagram illustrating a pixel arrangement in a display panel in some embodiments according to the present disclosure.

FIG. 5 is a schematic diagram illustrating a pixel arrangement in a display panel in some embodiments according to the present disclosure.

FIG. 6 is a schematic diagram illustrating a pixel arrangement in a display panel in some embodiments according to the present disclosure.

FIG. 7 is a cross-sectional view of a plurality of first pixels in a portion of a display panel in some embodiments according to the present disclosure.

FIG. 8 is a cross-sectional view of a plurality of second pixels in a portion of a display panel in some embodiments according to the present disclosure.

FIG. 9 is a plan view of a first black matrix in some embodiments according to the present disclosure.

FIG. 10 is a plan view of a second black matrix in some embodiments according to the present disclosure.

FIG. 11 is a superimposition of a first black matrix and a second black matrix in some embodiments according to the present disclosure.

FIG. 12 is a cross-sectional view of a plurality of first pixels in a portion of a display panel in some embodiments according to the present disclosure.

FIG. 13 is a cross-sectional view of a plurality of second pixels in a portion of a display panel in some embodiments according to the present disclosure.

FIG. 14 is a plan view of a first black matrix in some embodiments according to the present disclosure.

FIG. 15 is a plan view of a second black matrix in some embodiments according to the present disclosure.

FIG. 16 is a superimposition of a first black matrix and a second black matrix in some embodiments according to the present disclosure.

FIG. 17 is a cross-sectional view of a plurality of first pixels in a portion of a display panel in some embodiments according to the present disclosure.

FIG. 18 is a cross-sectional view of a plurality of second pixels in a portion of a display panel in some embodiments according to the present disclosure.

FIG. 19 is a plan view of a first black matrix in some embodiments according to the present disclosure.

FIG. 20 is a plan view of a second black matrix in some embodiments according to the present disclosure.

FIG. 21 is a superimposition of a first black matrix and a second black matrix in some embodiments according to the present disclosure.

FIG. 22 is a cross-sectional view of a plurality of first pixels in a portion of a display panel in some embodiments according to the present disclosure.

FIG. 23 is a cross-sectional view of a plurality of second pixels in a portion of a display panel in some embodiments according to the present disclosure.

FIG. 24 is a cross-sectional view of a plurality of second pixels in a portion of a display panel in alternative embodiments according to the present disclosure.

FIG. 25 is a plan view of a first black matrix in some embodiments according to the present disclosure.

FIG. 26 is a plan view of a second black matrix in some embodiments according to the present disclosure.

FIG. 27 is a superimposition of a first black matrix and a second black matrix in some embodiments according to the present disclosure.

FIG. 28 illustrates various parameters in a display panel in some embodiments according to the present disclosure.

FIG. 29 shows a correlation between luminance decay and a viewing angle in several embodiments according to the present disclosure.

FIG. 30 is a cross-sectional view of a plurality of second pixels in a portion of a display panel in some embodiments according to the present disclosure.

FIG. 31 is a cross-sectional view of a plurality of second pixels in a portion of a display panel in some embodiments according to the present disclosure.

FIG. 32 is a cross-sectional view of a plurality of second pixels in a portion of a display panel in some embodiments according to the present disclosure.

FIG. 33 illustrates various parameters in a display panel in some embodiments according to the present disclosure.

FIG. 34 illustrates various parameters in a display panel in some embodiments according to the present disclosure.

FIG. 35 illustrates various parameters in a display panel in some embodiments according to the present disclosure.

FIG. 36 illustrates various parameters in a display panel in some embodiments according to the present disclosure.

FIG. 37 shows a correlation between luminance decay and a viewing angle in several embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a display panel and a display apparatus that substantially obviate one or more of the problems due to limitations and disadvantages of the related art. In one aspect, the present disclosure provides a display panel. In some embodiments, the display panel includes a plurality of first pixels; a plurality of second pixels; a first black matrix; and a second black matrix. Optionally, the first black matrix is at least partially present in regions having the plurality of first pixels and regions having the plurality of second pixels. Optionally, the second black matrix is at least partially present in the regions having the plurality of second pixels, and at least partially absent in the regions having the plurality of first pixels. Optionally the second black matrix is present in the regions having the plurality of second pixels, and absent in the regions having the plurality of first pixels.

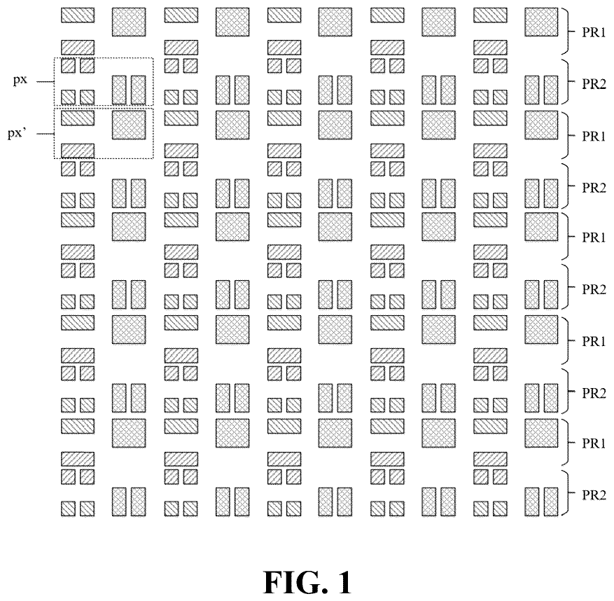

FIG. 1 is a schematic diagram illustrating a pixel arrangement in a display panel in some embodiments according to the present disclosure. Referring to FIG. 1, the display panel in some embodiments includes a plurality of first pixel rows PR1 and a plurality of second pixel rows PR2. Optionally, the display panel in some embodiments includes a plurality of first pixel rows PR1 and a plurality of second pixel rows PR2 alternately arranged. Optionally two adjacent first pixel rows of the plurality of first pixel rows PR1 are spaced apart by an individual second pixel row of the plurality of second pixel rows PR2. Two adjacent second pixel rows of the plurality of second pixel rows PR2 are spaced apart by an individual first pixel row of the plurality of first pixel rows PR1.

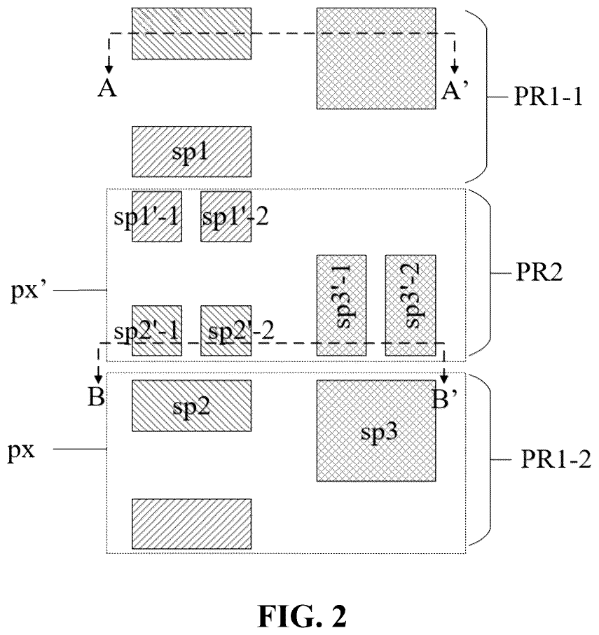

In some embodiments, a respective first pixel row of the plurality of first pixel rows PR1 includes a plurality of first pixels px sequentially arranged. A respective second pixel row of the plurality of second pixel rows PR2 includes a plurality of second pixels px′ sequentially arranged. FIG. 2 illustrates the structure of a portion of a display panel in some embodiments according to the present disclosure. Referring to FIG. 1 and FIG. 2, in some embodiments, a respective first pixel of the plurality of first pixels px includes a first subpixel sp1, a second subpixel sp2, and a third subpixel sp3. In some embodiments, a respective second pixel of the plurality of second pixels px′ includes one or more fourth subpixels, one or more fifth subpixels, and one or more sixth subpixels. In one example depicted in FIG. 1 and FIG. 2, the respective second pixel includes multiple fourth subpixels (e.g., subpixels sp1′-1 and sp1′-2), multiple fifth subpixels (e.g., sp2′-1 and sp2′-2), and multiple sixth subpixels (e.g., sp3′-1 and sp3′-2).

In an alternative example, the respective second pixel includes a single fourth subpixel, a single fifth subpixel, and a single sixth subpixel.

In an alternative example, the respective second pixel includes multiple fourth subpixels (e.g., subpixels sp1′-1 and sp1′-2), multiple fifth subpixels (e.g., sp2′-1 and sp2′-2), and a single sixth subpixel.

In an alternative example, the respective second pixel includes a single fourth subpixel, multiple fifth subpixels (e.g., sp2′-1 and sp2′-2), and multiple sixth subpixels (e.g., sp3′-1 and sp3′-2).

In an alternative example, the respective second pixel includes multiple fourth subpixels (e.g., subpixels sp1′-1 and sp1′-2), a single fifth subpixel, and multiple sixth subpixels (e.g., sp3′-1 and sp3′-2).

In some embodiments, the first subpixel sp1 and multiple fourth subpixels are subpixels of a first color (e.g., a red color). In some embodiments, the second subpixel sp2 and multiple fifth subpixels are subpixels of a second color (e.g., a green color). In some embodiments, the third subpixel sp3 and multiple sixth subpixels are subpixels of a third color (e.g., a blue color).

In some embodiments, the display panel includes a unitary anode configured to provide data signals to the multiple fourth subpixels in the respective second pixel. In some embodiments, the display panel includes a unitary anode configured to provide data signals to the multiple fifth subpixels in the respective second pixel. In some embodiments, the display panel includes a unitary anode configured to provide data signals to the multiple sixth subpixels in the respective second pixel.

In alternative embodiments, the display panel includes multiple anodes configured to independently provide data signals to the multiple fourth subpixels in the respective second pixel, respectively.

In alternative embodiments, the display panel includes multiple anodes configured to independently provide data signals to the multiple fifth subpixels in the respective second pixel, respectively.

In alternative embodiments, the display panel includes multiple anodes configured to independently provide data signals to the multiple sixth subpixels in the respective second pixel, respectively.

In some embodiments, the display panel includes a unitary cathode for the multiple fourth subpixels in the respective second pixel and a first subpixel sp1 in a first pixel in a first adjacent first pixel row PR1-1. In some embodiments, the display panel includes a unitary light emitting layer for the multiple fourth subpixels in the respective second pixel and the first subpixel sp1 in the first pixel in the first adjacent first pixel row PR1-1. In some embodiments, the display panel includes two separate anodes, one for the multiple fourth subpixels in the respective second pixel, and one for the first subpixel sp1 in the first pixel in the first adjacent first pixel row PR1-1. The two separate anodes are independently controlled, and configured to receive independent data signals.

In some embodiments, the display panel includes a unitary cathode for the multiple fifth subpixels in the respective second pixel and a second subpixel sp2 in a first pixel in a second adjacent first pixel row PR1-2. The respective second pixel is in a second pixel row spacing apart the first adjacent first pixel row PR1-1 and the second adjacent first pixel row PR1-2. In some embodiments, the display panel includes a unitary light emitting layer for the multiple fifth subpixels in the respective second pixel and the second subpixel sp2 in the first pixel in the second adjacent first pixel row PR1-2. In some embodiments, the display panel includes two separate anodes, one for the multiple fifth subpixels in the respective second pixel, and one for the second subpixel sp2 in the first pixel in the second adjacent first pixel row PR1-2. The two separate anodes are independently controlled, and configured to receive independent data signals.

In some embodiments, the display panel includes a unitary cathode for the multiple sixth subpixels in the respective second pixel and a third subpixel sp3 in the first pixel in the second adjacent first pixel row PR1-2. In some embodiments, the display panel includes a unitary light emitting layer for the multiple sixth subpixels in the respective second pixel and the third subpixel sp3 in the first pixel in the second adjacent first pixel row PR1-2. In some embodiments, the display panel includes two separate anodes, one for the multiple sixth subpixels in the respective second pixel, and one for the third subpixel sp3 in the first pixel in the second adjacent first pixel row PR1-2. The two separate anodes are independently controlled, and configured to receive independent data signals.

In some embodiments, the display panel is configured to operate in a first mode, a second mode, or a third mode. In the first mode, first pixels in the plurality of first pixel rows PR1 and second pixels in the plurality of second pixel rows PR2 are configured to emit light.

In the second mode, the second pixels in the plurality of second pixel rows PR2 are configured to display an image (e.g., emit light), whereas the first pixels in the plurality of first pixel rows PR1 are not configured to display an image (e.g., not emit light). In some embodiments, the second mode is a privacy mode. In the third mode, the second pixels in the plurality of second pixel rows PR2 are not configured to display an image (e.g., emit light), whereas the first pixels in the plurality of first pixel rows PR1 are configured to display an image (e.g., emit light).

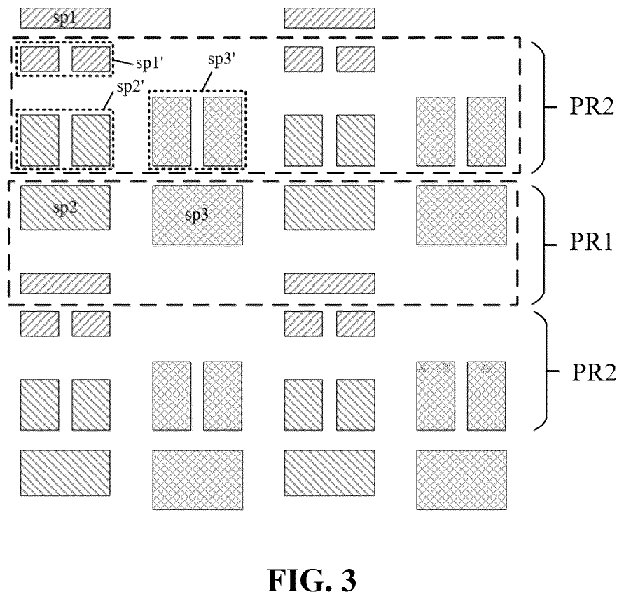

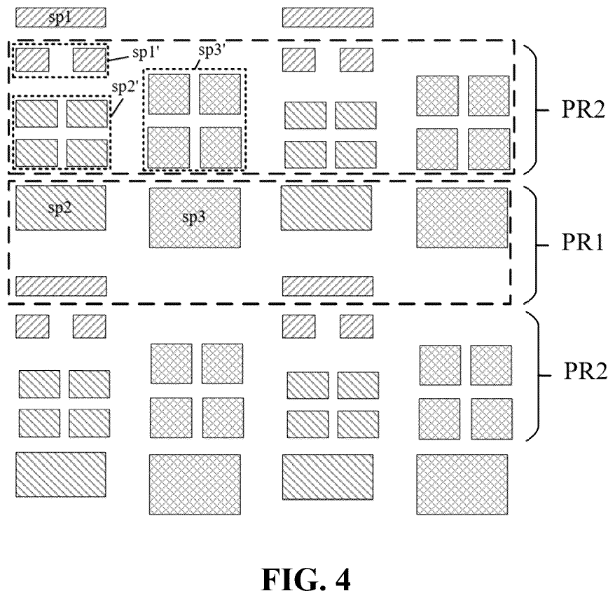

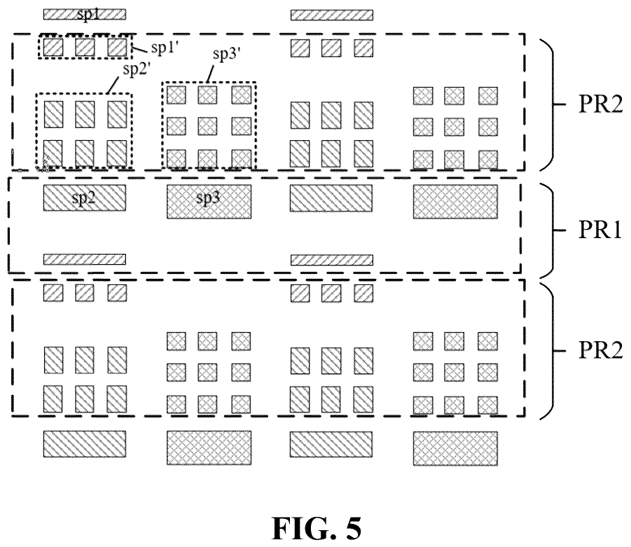

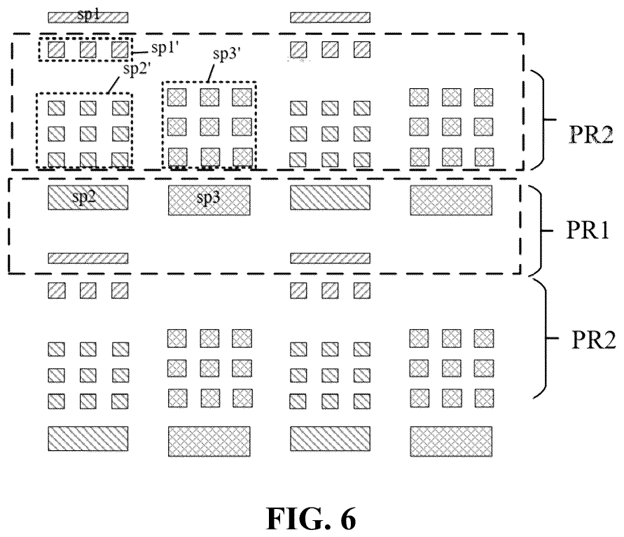

FIG. 3 is a schematic diagram illustrating a pixel arrangement in a display panel in some embodiments according to the present disclosure. FIG. 4 is a schematic diagram illustrating a pixel arrangement in a display panel in some embodiments according to the present disclosure. FIG. 5 is a schematic diagram illustrating a pixel arrangement in a display panel in some embodiments according to the present disclosure. FIG. 6 is a schematic diagram illustrating a pixel arrangement in a display panel in some embodiments according to the present disclosure. Referring to FIG. 3 to FIG. 6, in some embodiments, a respective first pixel of the plurality of first pixels includes a first subpixel sp1, a second subpixel sp2, and a third subpixel sp3. In some embodiments, a respective second pixel of the plurality of second pixels includes multiple fourth subpixels sp1′, multiple fifth subpixels sp2′, and multiple sixth subpixels sp3′. In FIG. 3, the total number of the multiple fourth subpixels sp1′ is 2, the total number of the multiple fifth subpixels sp2′ is 2, and the total number of the multiple sixth subpixels sp3′ is 2. In FIG. 4, the total number of the multiple fourth subpixels sp1′ is 2, the total number of the multiple fifth subpixels sp2′ is 4, and the total number of the multiple sixth subpixels sp3′ is 4. In FIG. 5, the total number of the multiple fourth subpixels sp1′ is 3, the total number of the multiple fifth subpixels sp2′ is 6, and the total number of the multiple sixth subpixels sp3′ is 9. In FIG. 6, the total number of the multiple fourth subpixels sp1′ is 3, the total number of the multiple fifth subpixels sp2′ is 9, and the total number of the multiple sixth subpixels sp3′ is 9. In general, the larger the area assigned to subpixels of a same color in a same pixel, the greater the number of subpixels of the same color in the same pixel. In some embodiments, a ratio of areas between a respective fourth subpixel, a respective fifth subpixel, or a respective sixth subpixel is in a range of 0.5 to 2.0, e.g., 0.75 to 1.5, or 0.85 to 1.75. In some embodiments, a ratio of a number of the multiple fourth subpixels sp1′, a number of the multiple fifth subpixels sp2′, and a number of the multiple sixth subpixels sp3′ is in a range of 1 to 3, e.g., 1, 2, or 3.

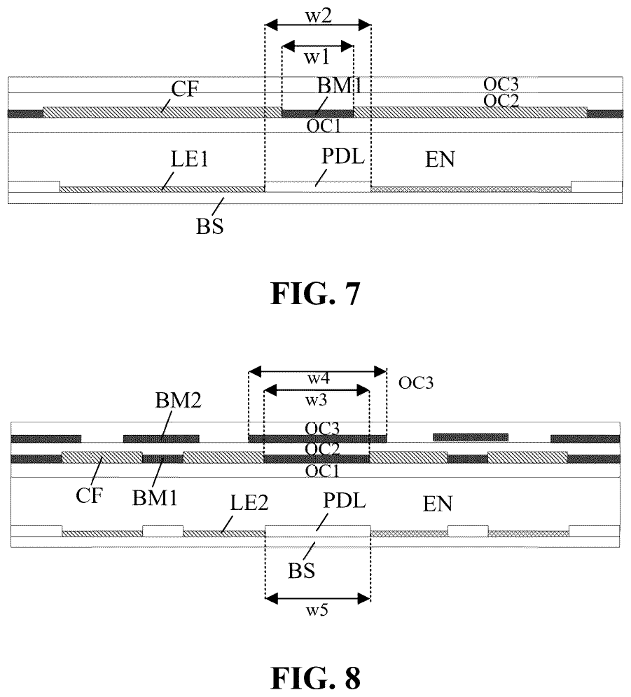

FIG. 7 is a cross-sectional view of a plurality of first pixels in a portion of a display panel in some embodiments according to the present disclosure. FIG. 7 may be a cross-sectional view along an A-A′ line in FIG. 2. Referring to FIG. 7, the portion of the display panel having the plurality of first pixels includes a base substrate BS; a pixel definition layer PDL on the base substrate BS, and defining a plurality of first subpixel apertures, a plurality of first light emitting elements LE1 at least partially received in the plurality of first subpixel apertures; an encapsulating layer EN on a side of the pixel definition layer PDL and the plurality of first light emitting elements LE1 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; and a third overcoat layer OC3 on a side of the second overcoat layer OC2 away from the base substrate BS. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 15 μm.

In some embodiments, in the portion of the display panel having the plurality of first pixels, an orthographic projection of the first black matrix BM1 on the base substrate BS at least partially overlaps with an orthographic projection of the pixel definition layer PDL on the base substrate BS. In some embodiments, in the portion of the display panel having the plurality of first pixels, a portion of the first black matrix BM1 between two adjacent subpixels has a first width w1 along a plane intersecting the two adjacent subpixels and the portion of the first black matrix BM1 and perpendicular to a surface of the base substrate BS, a portion of the pixel definition layer PDL between the same two adjacent subpixels has a second width w2 along a plane intersecting the two adjacent subpixels and the portion of the pixel definition layer PDL and perpendicular to the surface of the base substrate BS, the second width w2 is greater than the first width w1. In one example, the second width w2 is greater than the first width w1 by 2 μm to 4 μm.

FIG. 8 is a cross-sectional view of a plurality of second pixels in a portion of a display panel in some embodiments according to the present disclosure. FIG. 8 may be a cross-sectional view along a B-B′ line in FIG. 2. Referring to FIG. 8, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; a second black matrix BM2 on a side of the second overcoat layer OC2 away from the base substrate BS; and a third overcoat layer OC3 on a side of the second black matrix BM2 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 15 μm. In another example, the third overcoat layer OC3 has a thickness in a range of 3 μm to 5 μm.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; and an orthographic projection of the second black matrix BM2 on the base substrate BS at least partially overlaps with an orthographic projection of the pixel definition layer PDL on the base substrate BS.

In some embodiments, in the portion of the display panel having the plurality of second pixels, a portion of the first black matrix BM1 between two adjacent subpixels has a third width w3 along a plane intersecting the two adjacent subpixels and the portion of the first black matrix BM1 and perpendicular to a surface of the base substrate BS, a portion of the second black matrix BM2 between the same two adjacent subpixels has a fourth width w4 along a plane intersecting the two adjacent subpixels and the portion of the second black matrix BM2 and perpendicular to a surface of the base substrate BS, a portion of the pixel definition layer PDL between the same two adjacent subpixels has a fifth width w5 along a plane intersecting the two adjacent subpixels and the portion of the pixel definition layer PDL and perpendicular to the surface of the base substrate BS.

Optionally, the third width w3 is substantially the same as the fifth width w5. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5% not exceeding 0.1%, not exceeding 0.05%, and not exceeding 0.01%, of the base value.

Optionally, the fourth width w4 is greater than the fifth width w5. In one example, the fourth width w4 is greater than the fifth width w5 by 2 μm to 4 μm.

In some embodiments, the fourth width w4 is greater than the third width w3, the second width w2 is greater than the first width w1. Optionally, the fourth width w4 is greater than the second width w2. Optionally, the third width w3 is greater than the first width w1.

In some embodiments, in the portion of the display panel having the plurality of second pixels, a first portion of the first black matrix BM1 between two adjacent subpixels of a same color has a first portion width along a plane intersecting the two adjacent subpixels of the same color and the first portion of the first black matrix BM1 and perpendicular to a surface of the base substrate BS, a second portion of the first black matrix BM1 between two adjacent subpixels of different colors has a second portion width along a plane intersecting the two adjacent subpixels of different colors and the second portion of the first black matrix BM1 and perpendicular to a surface of the base substrate BS. In some embodiments, the second portion width is greater than the first portion width.

In some embodiments, in the portion of the display panel having the plurality of second pixels, a first portion of the second black matrix BM2 between two adjacent subpixels of a same color has a third portion width along a plane intersecting the two adjacent subpixels of the same color and the first portion of the second black matrix BM2 and perpendicular to a surface of the base substrate BS, a second portion of the second black matrix BM2 between two adjacent subpixels of different colors has a fourth portion width along a plane intersecting the two adjacent subpixels of different colors and the second portion of the second black matrix BM2 and perpendicular to a surface of the base substrate BS. In some embodiments, the fourth portion width is greater than the third portion width.

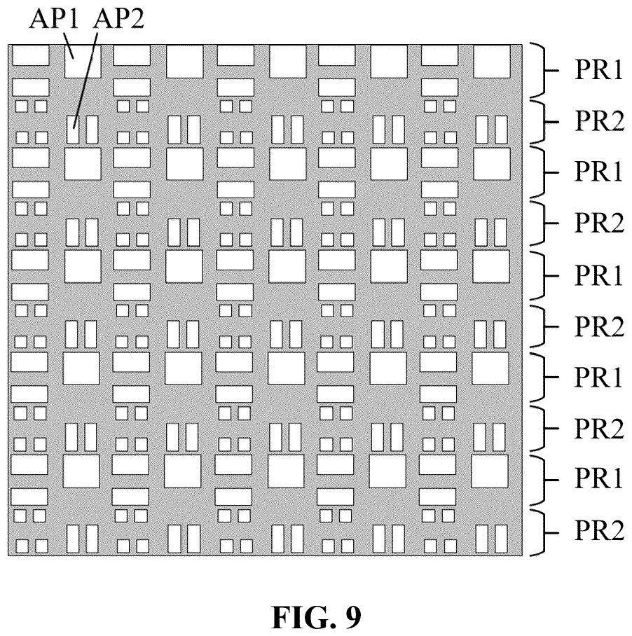

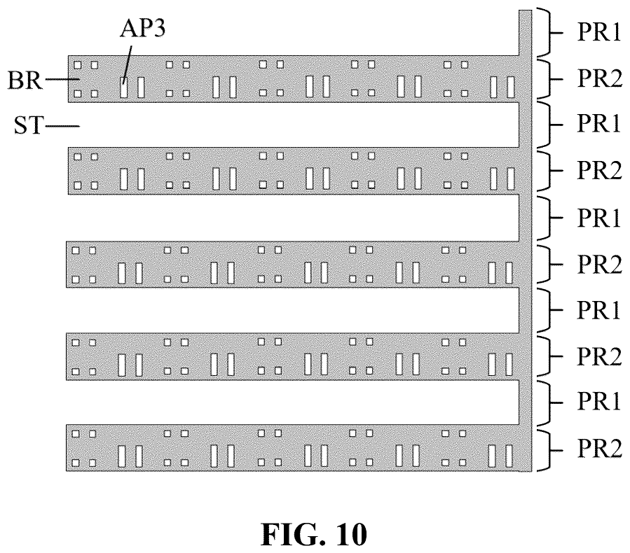

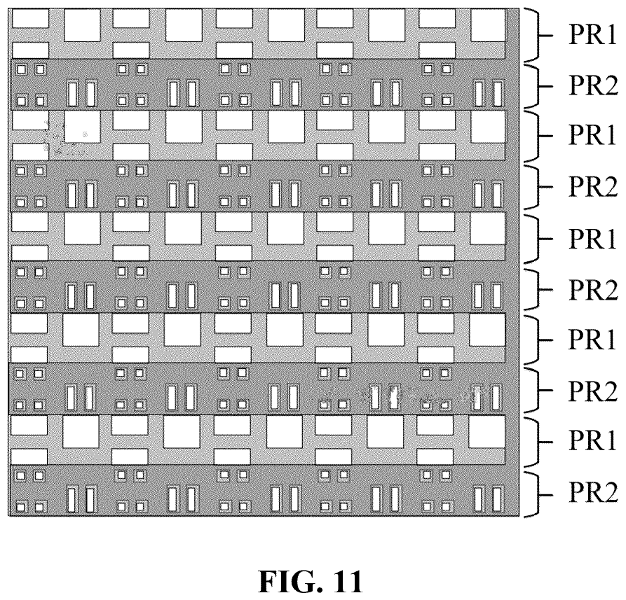

FIG. 9 is a plan view of a first black matrix in some embodiments according to the present disclosure. FIG. 10 is a plan view of a second black matrix in some embodiments according to the present disclosure. FIG. 11 is a superimposition of a first black matrix and a second black matrix in some embodiments according to the present disclosure. Referring to FIG. 9 to FIG. 11, the first black matrix BM1 is at least partially present in regions corresponding to the plurality of first pixel rows PR1 and a plurality of second pixel rows PR2, whereas the second black matrix BM2 is at least partially absent in regions corresponding to the plurality of first pixel rows PR1, and at least partially present in regions corresponding to the plurality of second pixel rows PR2.

In some embodiments, the regions corresponding to the plurality of first pixel rows PR1 is substantially absent (e.g., at least 50% absent, at least 55% absent, at least 60% absent, at least 65% absent, at least 70% absent, at least 75% absent, at least 80% absent, at least 85% absent, at least 90% absent, at least 95% absent, at least 99% absent, or completely absent) of the second black matrix BM2.

In some embodiments, in regions corresponding to the plurality of first pixel rows PR1, an orthographic projection of the first black matrix BM1 on a base substrate is substantially non-overlapping (e.g., at least 50% non-overlapping, at least 55% non-overlapping, at least 60% non-overlapping, at least 65% non-overlapping, at least 70% non-overlapping, at least 75% non-overlapping, at least 80% non-overlapping, at least 85% non-overlapping, at least 90% non-overlapping, at least 95% non-overlapping, at least 99% non-overlapping, completely non-overlapping,) with an orthographic projection of the second black matrix BM2 on the base substrate.

In some embodiments, in regions corresponding to the plurality of second pixel rows PR2, the orthographic projection of the first black matrix BM1 on the base substrate at least partially (e.g., at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 99%) overlaps with the orthographic projection of the second black matrix BM2 on the base substrate.

In some embodiments, the second black matrix BM2 includes a plurality of bars BR, and the display panel includes a plurality of slits ST, the plurality of bars BR and the plurality of slits ST are alternately arranged. Two adjacent bars of the plurality of bars BR are spaced apart by a slit of the plurality of slits ST. Two adjacent slits of the plurality of slits ST are spaced apart by a bar of the plurality of bars BR. The plurality of bars BR correspond to the plurality of second pixel rows PR2. The plurality of slits ST correspond to the plurality of first pixel rows PR1.

In some embodiments, the display panel includes a plurality of first apertures AP1 extending through the first black matrix BM1, and a plurality of second apertures AP2 extending through the first black matrix BM1. The plurality of first apertures AP1 are configured to allow light emitted from a plurality of first light emitting elements in the plurality of first subpixels to transmit through, the plurality of second apertures AP2 are configured to allow light emitted from a plurality of second light emitting elements in the plurality of second subpixels to transmit through.

In some embodiments, a respective slit of the plurality of slits ST is a continuous slit. In some embodiments, the respective slit has a bar shape. In some embodiments, an area of the respective slit is greater than a combined area of multiple first apertures of the plurality of first apertures AP1 in a respective first pixel row of the plurality of first pixel rows PR1.

In some embodiments, the display panel includes a plurality of third apertures AP3 extending through the second black matrix BM2. The plurality of third apertures AP3 are configured to allow light emitted from a plurality of second light emitting elements in the plurality of second subpixels to transmit through.

In some embodiments, in the portion of the display panel having the plurality of second pixels, a second aperture of the plurality of second apertures AP2 configured to allow light emitted from a second light emitting element to transmit through has a first aperture width along a plane intersecting the two adjacent second subpixels and perpendicular to a surface of the base substrate, a third aperture of the plurality of third apertures AP3 configured to allow light emitted from a same second light emitting element to transmit through has a second aperture width along the plane intersecting the two adjacent second subpixels and perpendicular to the surface of the base substrate. Optionally, the first aperture width is greater than the second aperture width. In one example, the first aperture width is greater than the second aperture width by 2 μm to 4 μm.

In some embodiments, an orthographic projection of an edge of a second aperture of the plurality of second apertures AP2 configured to allow light emitted from a second light emitting element to transmit through on a base substrate substantially surrounds (e.g., at least 50% surrounds, at least 55% surrounds, at least 60% surrounds, at least 65% surrounds, at least 70% surrounds, at least 75% surrounds, at least 80% surrounds, at least 85% surrounds, at least 90% surrounds, at least 95% surrounds, at least 99% surrounds, or completely surrounds) an orthographic projection of an edge of a third aperture of the plurality of third apertures AP3 configured to allow light emitted from a same second light emitting element to transmit through on the base substrate. In some embodiments, with respect to a same second subpixel. an area of a respective second aperture of the plurality of second apertures AP2 is greater than a respective third aperture of the plurality of third apertures AP3. In some embodiments, with respect to a subpixel of a same color, an area of a respective first aperture of the plurality of first apertures AP1 is greater than an area of a respective second aperture of the plurality of second apertures AP2, which is greater than an area of a respective third aperture of the plurality of third apertures AP3. The inventors of the present disclosure discover that, by having this structure, light transmission in the subpixel can be controlled.

The inventors of the present disclosure discover that, when the display panel is operated in the second mode, the display panel having the structure according to the present disclosure can effectively reduce the anti-peeping viewing angle. In one example, the left and right sides' 45° Luminance Decay ratio in the display panel according to the present disclosure can be reduced to 7%, and the upper side's 45° Luminance Decay ratio in the display panel according to the present disclosure can be reduced to 4%.

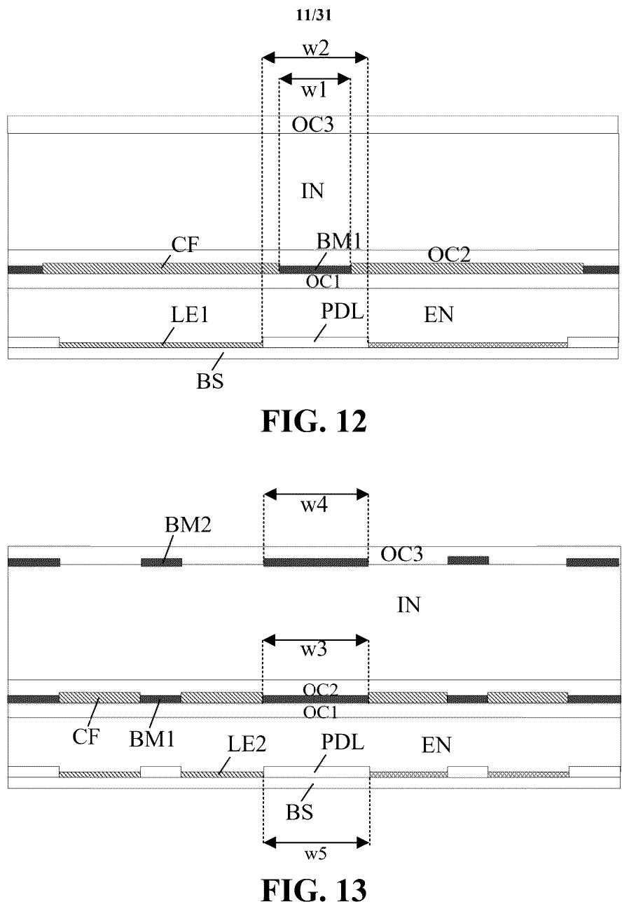

FIG. 12 is a cross-sectional view of a plurality of first pixels in a portion of a display panel in some embodiments according to the present disclosure. Referring to FIG. 12, the portion of the display panel having the plurality of first pixels includes a base substrate BS; a pixel definition layer PDL on the base substrate BS, and defining a plurality of first subpixel apertures, a plurality of first light emitting elements LE1 at least partially received in the plurality of first subpixel apertures; an encapsulating layer EN on a side of the pixel definition layer PDL and the plurality of first light emitting elements LE1 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; an insulating layer IN on a side of the second overcoat layer OC2 away from the base substrate BS; and a third overcoat layer OC3 on a side of the insulating layer IN away from the base substrate BS. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 8 μm. In another example, the insulating layer IN has a thickness in a range of 10 μm to 40 μm. In another example, the third overcoat layer OC3 has a thickness in a range of 2 μm to 4 μm.

In some embodiments, in the portion of the display panel having the plurality of first pixels, an orthographic projection of the first black matrix BM1 on the base substrate BS at least partially overlaps with an orthographic projection of the pixel definition layer PDL on the base substrate BS. In some embodiments, in the portion of the display panel having the plurality of first pixels, a portion of the first black matrix BM1 between two adjacent subpixels has a first width w1 along a plane intersecting the two adjacent subpixels and the portion of the first black matrix BM1 and perpendicular to a surface of the base substrate BS, a portion of the pixel definition layer PDL between the same two adjacent subpixels has a second width w2 along a plane intersecting the two adjacent subpixels and the portion of the pixel definition layer PDL and perpendicular to the surface of the base substrate BS. Optionally, the second width w2 is greater than the first width w1. In one example, the second width w2 is greater than the first width w1 by 2 μm to 4 μm.

FIG. 13 is a cross-sectional view of a plurality of second pixels in a portion of a display panel in some embodiments according to the present disclosure. Referring to FIG. 13, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; an insulating layer IN on a side of the second overcoat layer OC2 away from the base substrate BS; a second black matrix BM2 on a side of the insulating layer IN away from the base substrate BS; and a third overcoat layer OC3 on a side of the second black matrix BM2 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 8 μm. In another example, the insulating layer IN has a thickness in a range of 10 μm to 40 μm. In another example, the third overcoat layer OC3 has a thickness in a range of 2 μm to 4 μm.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; and an orthographic projection of the second black matrix BM2 on the base substrate BS at least partially overlaps with an orthographic projection of the pixel definition layer PDL on the base substrate BS.

In some embodiments, in the portion of the display panel having the plurality of second pixels, a portion of the first black matrix BM1 between two adjacent subpixels has a third width w3 along a plane intersecting the two adjacent subpixels and the portion of the first black matrix BM1 and perpendicular to a surface of the base substrate BS, a portion of the second black matrix BM2 between the same two adjacent subpixels has a fourth width w4 along a plane intersecting the two adjacent subpixels and the portion of the second black matrix BM2 and perpendicular to a surface of the base substrate BS, a portion of the pixel definition layer PDL between the same two adjacent subpixels has a fifth width w5 along a plane intersecting the two adjacent subpixels and the portion of the pixel definition layer PDL and perpendicular to the surface of the base substrate BS.

Optionally, the third width w3 is substantially the same as the fifth width w5.

Optionally, the fourth width w4 is substantially the same as the fifth width w5.

Optionally, the third width w3 is substantially the same as the fourth width w4.

Optionally, the third width w3, the fourth width w4, and the fifth width w5 are substantially the same.

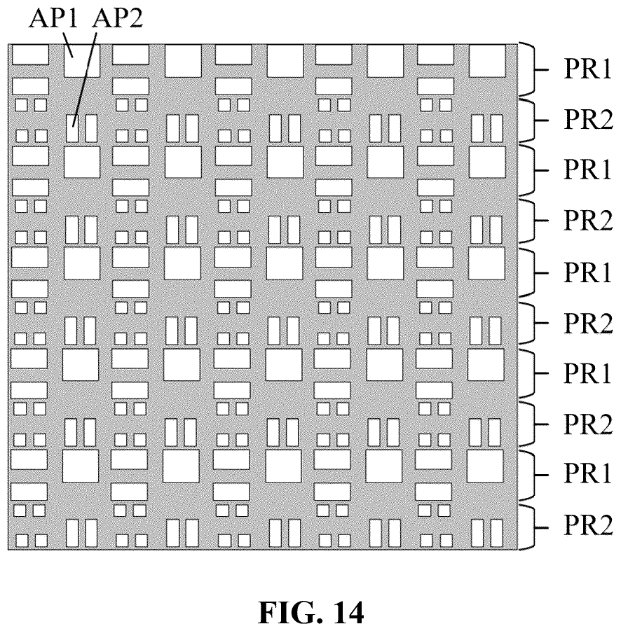

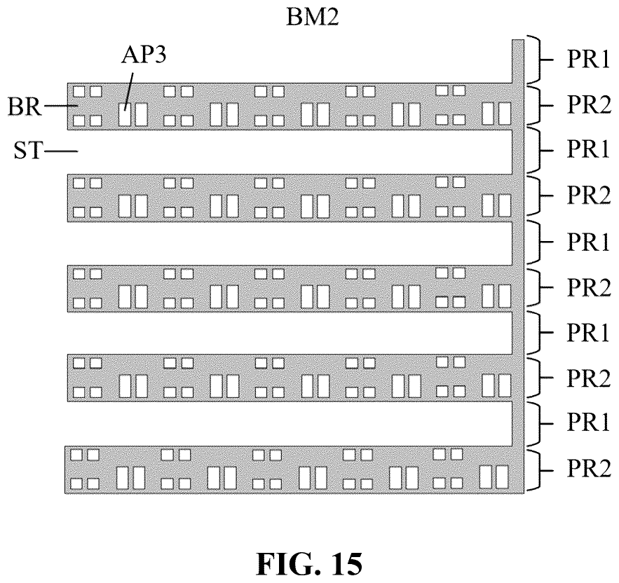

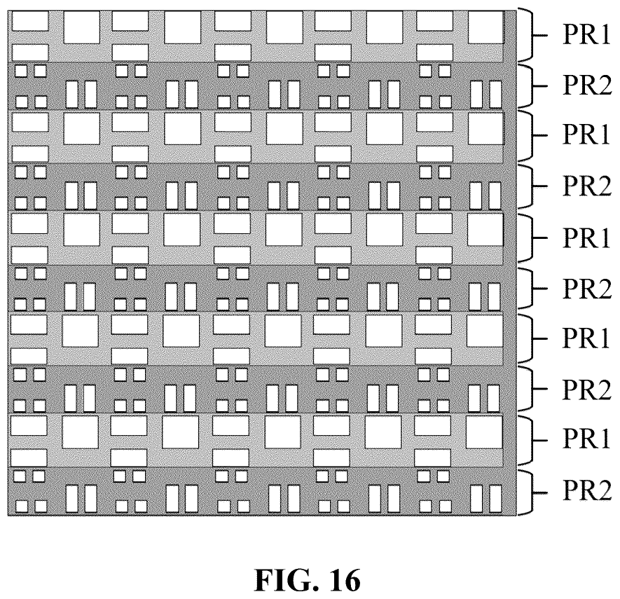

FIG. 14 is a plan view of a first black matrix in some embodiments according to the present disclosure. FIG. 15 is a plan view of a second black matrix in some embodiments according to the present disclosure. FIG. 16 is a superimposition of a first black matrix and a second black matrix in some embodiments according to the present disclosure. Referring to FIG. 14 to FIG. 16, the first black matrix BM1 is at least partially present in regions corresponding to the plurality of first pixel rows PR1 and a plurality of second pixel rows PR2, whereas the second black matrix BM2 is at least partially absent in regions corresponding to the plurality of first pixel rows PR1, and at least partially present in regions corresponding to the plurality of second pixel rows PR2.

In some embodiments, the regions corresponding to the plurality of first pixel rows PR1 is substantially absent (e.g., at least 50% absent, at least 55% absent, at least 60% absent, at least 65% absent, at least 70% absent, at least 75% absent, at least 80% absent, at least 85% absent, at least 90% absent, at least 95% absent, at least 99% absent, or completely absent) of the second black matrix BM2.

In some embodiments, in regions corresponding to the plurality of first pixel rows PR1, an orthographic projection of the first black matrix BM1 on a base substrate is substantially non-overlapping (e.g., at least 50% non-overlapping, at least 55% non-overlapping, at least 60% non-overlapping, at least 65% non-overlapping, at least 70% non-overlapping, at least 75% non-overlapping, at least 80% non-overlapping, at least 85% non-overlapping, at least 90% non-overlapping, at least 95% non-overlapping, at least 99% non-overlapping, completely non-overlapping,) with an orthographic projection of the second black matrix BM2 on the base substrate.

In some embodiments, in regions corresponding to the plurality of second pixel rows PR2, the orthographic projection of the first black matrix BM1 on the base substrate at least partially (e.g., at least 10%, at least 15%, at least 20%, at least 25%, at least 30%, at least 35%. at least 40%, at least 45%, at least 50%, at least 55%, at least 60%, at least 65%, at least 70%; at least 75%, at least 80%, at least 85%, at least 90%, at least 95%, or at least 99%) overlaps with the orthographic projection of the second black matrix BM2 on the base substrate.

In some embodiments, the second black matrix BM2 includes a plurality of bars BR, and the display panel includes a plurality of slits ST, the plurality of bars BR and the plurality of slits ST are alternately arranged. Two adjacent bars of the plurality of bars BR are spaced apart by a slit of the plurality of slits ST. Two adjacent slits of the plurality of slits ST are spaced apart by a bar of the plurality of bars BR. The plurality of bars BR correspond to the plurality of second pixel rows PR2. The plurality of slits ST correspond to the plurality of first pixel rows PR1 In some embodiments, the display panel includes a plurality of first apertures AP1 extending through the first black matrix BM1, and a plurality of second apertures AP2 extending through the first black matrix BM1. The plurality of first apertures AP1 are configured to allow light emitted from a plurality of first light emitting elements in the plurality of first subpixels to transmit through, the plurality of second apertures AP2 are configured to allow light emitted from a plurality of second light emitting elements in the plurality of second subpixels to transmit through.

In some embodiments, the display panel includes a plurality of third apertures AP3 extending through the second black matrix BM2. The plurality of third apertures AP3 are configured to allow light emitted from a plurality of second light emitting elements in the plurality of second subpixels to transmit through.

In some embodiments, in the portion of the display panel having the plurality of second pixels, a second aperture of the plurality of second apertures AP2 configured to allow light emitted from a second light emitting element to transmit through has a first aperture width along a plane intersecting the two adjacent second subpixels and perpendicular to a surface of the base substrate, a third aperture of the plurality of third apertures AP3 configured to allow light emitted from a same second light emitting element to transmit through has a second aperture width along the plane intersecting the two adjacent second subpixels and perpendicular to the surface of the base substrate. Optionally, the first aperture width and the second aperture width are substantially the same.

In some embodiments, an orthographic projection of an edge of a second aperture of the plurality of second apertures AP2 configured to allow light emitted from a second light emitting element to transmit through on a base substrate and an orthographic projection of an edge of a third aperture of the plurality of third apertures AP3 configured to allow light emitted from a same second light emitting element to transmit through on the base substrate substantially (e.g., at least 50%, at least 55%, at least 60%, at least 65%, at least 70%, at least 75%, at least 80%, at least 85%, at least 90%, at least 95%, at least 99%, or completely) overlap with each other.

The inventors of the present disclosure discover that, when the display panel is operated in the second mode, the display panel having the structure according to the present disclosure can effectively reduce the anti-peeping viewing angle. In one example, the left and right sides' 45° Luminance Decay ratio in the display panel according to the present disclosure can be reduced to 4%, and the upper side's 45° Luminance Decay ratio in the display panel according to the present disclosure can be reduced to 4%.

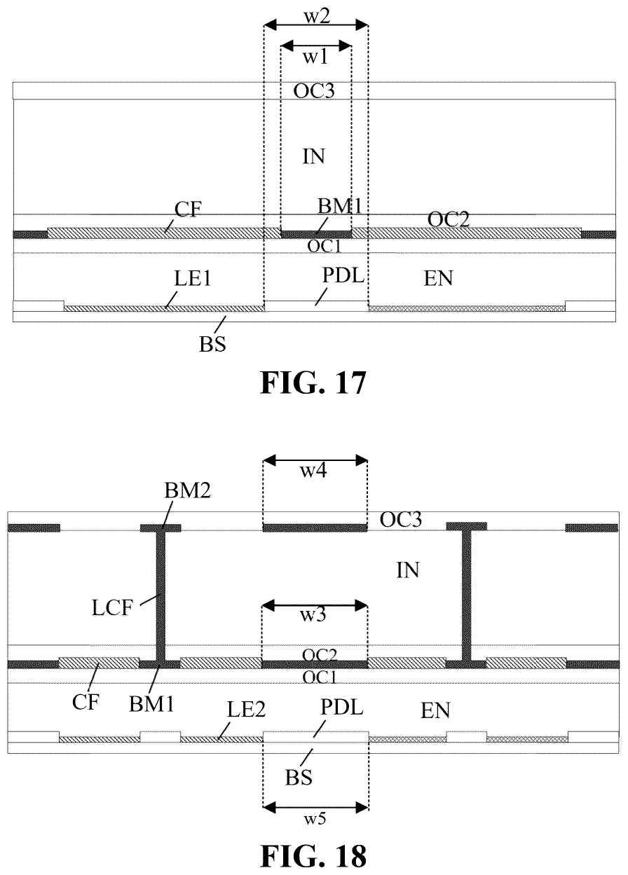

FIG. 17 is a cross-sectional view of a plurality of first pixels in a portion of a display panel in some embodiments according to the present disclosure. Referring to FIG. 17, the portion of the display panel having the plurality of first pixels includes a base substrate BS; a pixel definition layer PDL on the base substrate BS, and defining a plurality of first subpixel apertures, a plurality of first light emitting elements LE1 at least partially received in the plurality of first subpixel apertures; an encapsulating layer EN on a side of the pixel definition layer PDL and the plurality of first light emitting elements LE1 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; an insulating layer IN on a side of the second overcoat layer OC2 away from the base substrate BS; and a third overcoat layer OC3 on a side of the insulating layer IN away from the base substrate BS. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 8 μm. In another example, the insulating layer IN has a thickness in a range of 10 μm to 40 μm. In another example, the third overcoat layer OC3 has a thickness in a range of 2 μm to 4 μm.

In some embodiments, in the portion of the display panel having the plurality of first pixels, an orthographic projection of the first black matrix BM1 on the base substrate BS at least partially overlaps with an orthographic projection of the pixel definition layer PDL on the base substrate BS. In some embodiments, in the portion of the display panel having the plurality of first pixels, a portion of the first black matrix BM1 between two adjacent subpixels has a first width w1 along a plane intersecting the two adjacent subpixels and the portion of the first black matrix BM1 and perpendicular to a surface of the base substrate BS, a portion of the pixel definition layer PDL between the same two adjacent subpixels has a second width w2 along a plane intersecting the two adjacent subpixels and the portion of the pixel definition layer PDL and perpendicular to the surface of the base substrate BS. Optionally, the first width w1 and the second width w2 are substantially the same.

FIG. 18 is a cross-sectional view of a plurality of second pixels in a portion of a display panel in some embodiments according to the present disclosure. Referring to FIG. 18, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; an insulating layer IN on a side of the second overcoat layer OC2 away from the base substrate BS; a second black matrix BM2 on a side of the insulating layer IN away from the base substrate BS; and a third overcoat layer OC3 on a side of the second black matrix BM2 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 8 μm. In another example, the insulating layer IN has a thickness in a range of 10 μm to 40 μm. In another example, the third overcoat layer OC3 has a thickness in a range of 2 μm to 4 μm.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; and an orthographic projection of the second black matrix BM2 on the base substrate BS at least partially overlaps with an orthographic projection of the pixel definition layer PDL on the base substrate BS.

In some embodiments, in the portion of the display panel having the plurality of second pixels, a portion of the first black matrix BM1 between two adjacent subpixels has a third width w3 along a plane intersecting the two adjacent subpixels and the portion of the first black matrix BM1 and perpendicular to a surface of the base substrate BS, a portion of the second black matrix BM2 between the same two adjacent subpixels has a fourth width w4 along a plane intersecting the two adjacent subpixels and the portion of the second black matrix BM2 and perpendicular to a surface of the base substrate BS, a portion of the pixel definition layer PDL between the same two adjacent subpixels has a fifth width w5 along a plane intersecting the two adjacent subpixels and the portion of the pixel definition layer PDL and perpendicular to the surface of the base substrate BS.

Optionally, the third width w3 is substantially the same as the fifth width w5.

Optionally, the fourth width w4 is substantially the same as the fifth width w5.

Optionally, the third width w3 is substantially the same as the fourth width w4.

Optionally, the third width w3, the fourth width w4, and the fifth width w5 are substantially the same.

In some embodiments, in the portion of the display panel having the plurality of second pixels, the display panel further includes a light control structure LCF at least partially extending through the insulating layer IN. Optionally, the light control structure LCF is connected to a portion of the first black matrix BM1, and is connected to a portion of the second black matrix BM2. In one example, the light control structure LCF extends from the portion of the first black matrix BM1, through the insulating layer IN, and to the portion of the second black matrix BM2.

In some embodiments, the light control structure LCF is absent in a region between adjacent subpixels of different colors. In some embodiments, the light control structure LCF is present in at least one region between adjacent subpixels of a same color.

Various appropriate methods may be used for forming the light control structure LCF. For example, forming the light control structure LCF includes forming a via extending through the insulating layer IN, and depositing a black material into the via, thereby forming the light control structure LCF. In another example, forming the light control structure LCF includes coating a black material layer on the second overcoat layer OC2, patterning the black material layer to form at least a sub-layer of the light control structure LCF, and optionally repeating the coating and patterning steps at least one time, thereby forming the light control structure LCF. An insulating material layer can be then deposited on the substrate to planarize the substrate thereby forming the insulating layer IN.

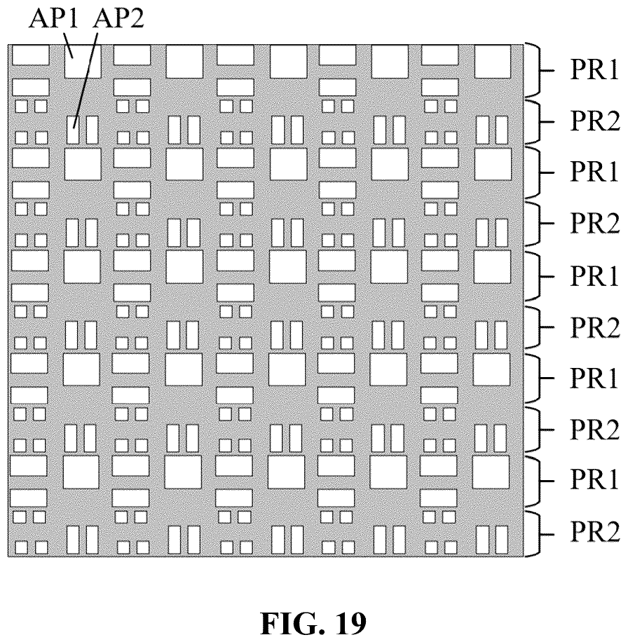

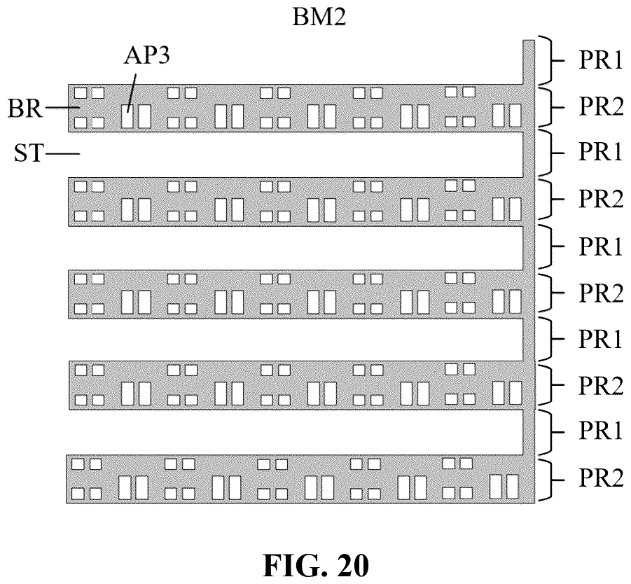

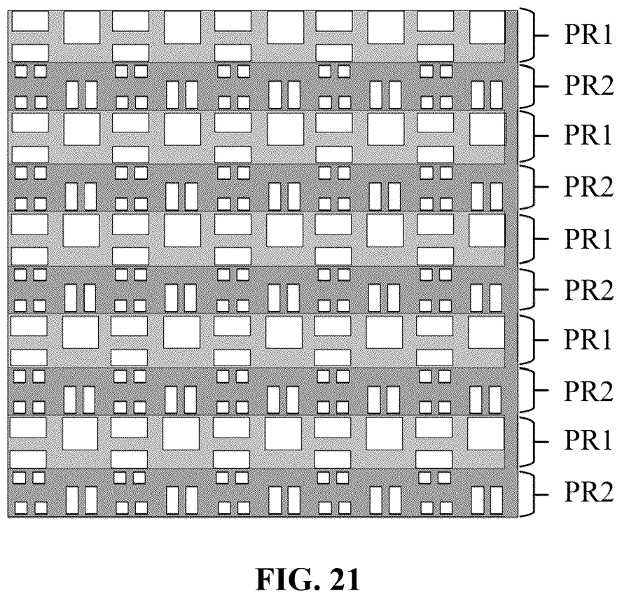

FIG. 19 is a plan view of a first black matrix in some embodiments according to the present disclosure. FIG. 20 is a plan view of a second black matrix in some embodiments according to the present disclosure. FIG. 21 is a superimposition of a first black matrix and a second black matrix in some embodiments according to the present disclosure. Referring to FIG. 19 to FIG. 21, the first black matrix BM1 is at least partially present in regions corresponding to the plurality of first pixel rows PR1 and a plurality of second pixel rows PR2, whereas the second black matrix BM2 is at least partially absent in regions corresponding to the plurality of first pixel rows PR1, and at least partially present in regions corresponding to the plurality of second pixel rows PR2.

In some embodiments, the regions corresponding to the plurality of first pixel rows PR1 is substantially absent (e.g., at least 50% absent, at least 55% absent, at least 60% absent, at least 65% absent, at least 70% absent, at least 75% absent, at least 80% absent, at least 85% absent, at least 90% absent, at least 95% absent, at least 99% absent, or completely absent) of the second black matrix BM2.

In some embodiments, in regions corresponding to the plurality of first pixel rows PR1, an orthographic projection of the first black matrix BM1 on a base substrate is substantially non-overlapping (e.g., at least 50% non-overlapping, at least 55% non-overlapping, at least 60% non-overlapping, at least 65% non-overlapping, at least 70% non-overlapping, at least 75% non-overlapping, at least 80% non-overlapping, at least 85% non-overlapping, at least 90% non-overlapping, at least 95% non-overlapping, at least 99% non-overlapping, completely non-overlapping,) with an orthographic projection of the second black matrix BM2 on the base substrate.

In some embodiments, in regions corresponding to the plurality of second pixel rows PR2, the orthographic projection of the first black matrix BM1 on the base substrate at least partially (e.g., at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 99%) overlaps with the orthographic projection of the second black matrix BM2 on the base substrate.

In some embodiments, the second black matrix BM2 includes a plurality of bars BR, and the display panel includes a plurality of slits ST, the plurality of bars BR and the plurality of slits ST are alternately arranged. Two adjacent bars of the plurality of bars BR are spaced apart by a slit of the plurality of slits ST. Two adjacent slits of the plurality of slits ST are spaced apart by a bar of the plurality of bars BR. The plurality of bars BR correspond to the plurality of second pixel rows PR2. The plurality of slits ST correspond to the plurality of first pixel rows PR1.

In some embodiments, the display panel includes a plurality of first apertures AP1 extending through the first black matrix BM1, and a plurality of second apertures AP2 extending through the first black matrix BM1. The plurality of first apertures AP1 are configured to allow light emitted from a plurality of first light emitting elements in the plurality of first subpixels to transmit through, the plurality of second apertures AP2 are configured to allow light emitted from a plurality of second light emitting elements in the plurality of second subpixels to transmit through.

In some embodiments, the display panel includes a plurality of third apertures AP3 extending through the second black matrix BM2. The plurality of third apertures AP3 are configured to allow light emitted from a plurality of second light emitting elements in the plurality of second subpixels to transmit through.

In some embodiments, in the portion of the display panel having the plurality of second pixels, a second aperture of the plurality of second apertures AP2 configured to allow light emitted from a second light emitting element to transmit through has a first aperture width along a plane intersecting the two adjacent second subpixels and perpendicular to a surface of the base substrate, a third aperture of the plurality of third apertures AP3 configured to allow light emitted from a same second light emitting element to transmit through has a second aperture width along the plane intersecting the two adjacent second subpixels and perpendicular to the surface of the base substrate. Optionally, the first aperture width and the second aperture width are substantially the same.

In some embodiments, an orthographic projection of an edge of a second aperture of the plurality of second apertures AP2 configured to allow light emitted from a second light emitting element to transmit through on a base substrate and an orthographic projection of an edge of a third aperture of the plurality of third apertures AP3 configured to allow light emitted from a same second light emitting element to transmit through on the base substrate substantially (e.g., at least 50%, at least 55%, at least 60%, at least 65%, at least 70%, at least 75%, at least 80%, at least 85%, at least 90%, at least 95%, at least 99%, or completely) overlap with each other.

The inventors of the present disclosure discover that, when the display panel is operated in the second mode, the display panel having the structure according to the present disclosure can effectively reduce the anti-peeping viewing angle. In one example, the left and right sides' 45° Luminance Decay ratio in the display panel according to the present disclosure can be reduced to 3%, and the upper side's 45° Luminance Decay ratio in the display panel according to the present disclosure can be reduced to 3%.

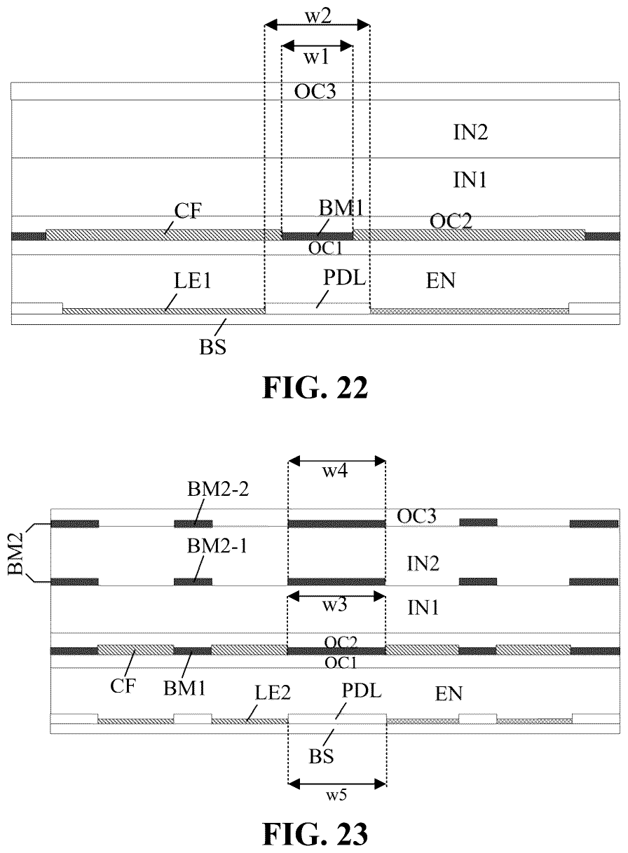

FIG. 22 is a cross-sectional view of a plurality of first pixels in a portion of a display panel in some embodiments according to the present disclosure. Referring to FIG. 22, the portion of the display panel having the plurality of first pixels includes a base substrate BS; a pixel definition layer PDL on the base substrate BS, and defining a plurality of first subpixel apertures, a plurality of first light emitting elements LE1 at least partially received in the plurality of first subpixel apertures; an encapsulating layer EN on a side of the pixel definition layer PDL and the plurality of first light emitting elements LE1 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; a first insulating layer IN1 on a side of the second overcoat layer OC2 away from the base substrate BS; a second insulating layer IN2 on a side of the first insulating layer IN1 away from the base substrate BS; and a third overcoat layer OC3 on a side of the second insulating layer IN2 away from the base substrate BS. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 8 μm. In another example, the insulating layer IN has a thickness in a range of 10 μm to 40 μm. In another example, the third overcoat layer OC3 has a thickness in a range of 2 μm to 4 μm.

In some embodiments, in the portion of the display panel having the plurality of first pixels, an orthographic projection of the first black matrix BM1 on the base substrate BS at least partially overlaps with an orthographic projection of the pixel definition layer PDL on the base substrate BS. In some embodiments, in the portion of the display panel having the plurality of first pixels, a portion of the first black matrix BM1 between two adjacent subpixels has a first width w1 along a plane intersecting the two adjacent subpixels and the portion of the first black matrix BM1 and perpendicular to a surface of the base substrate BS, a portion of the pixel definition layer PDL between the same two adjacent subpixels has a second width w2 along a plane intersecting the two adjacent subpixels and the portion of the pixel definition layer PDL and perpendicular to the surface of the base substrate BS. Optionally, the first width w1 and the second width w2 are substantially the same.

FIG. 23 is a cross-sectional view of a plurality of second pixels in a portion of a display panel in some embodiments according to the present disclosure. Referring to FIG. 23, the second black matrix BM2 in some embodiments includes multiple sub-layers, e.g., a first sub-layer BM2-1 and a second sub-layer BM2-2. In some embodiments, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; a first insulating layer IN1 on a side of the second overcoat layer OC2 away from the base substrate BS; a first sub-layer BM2-1 of a second black matrix BM2 on a side of the first insulating layer IN1 away from the base substrate BS; a second insulating layer IN2 on a side of the first sub-layer BM2-1 of the second black matrix BM2 away from the base substrate BS; a second sub-layer BM2-2 of the second black matrix BM2 on a side of the second insulating layer IN2 away from the base substrate BS; and a third overcoat layer OC3 on a side of the second sub-layer BM2-2 of the second black matrix BM2 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to μm. In another example, the first insulating layer IN1 and the second insulating layer IN2 have a combined thickness in a range of 10 μm to 40 μm. In another example, the third overcoat layer OC3 has a thickness in a range of 2 μm to 4 μm. In another example, two adjacent sub-layers of the second black matrix BM2 are spaced apart by a distance in a range of 5 μm to 15 μm. In some embodiments, a thickness of the first insulating layer IN1 is greater than a thickness of the third overcoat layer OC3, greater than a thickness of the second overcoat layer OC2, and greater than a thickness of the first overcoat layer OC1. In some embodiments, a thickness of the second insulating layer IN2 is greater than a thickness of the third overcoat layer OC3, greater than a thickness of the second overcoat layer OC2, and greater than a thickness of the first overcoat layer OC1.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; an orthographic projection of the first sub-layer BM2-1 of the second black matrix BM2 on the base substrate BS at least partially overlaps with an orthographic projection of the pixel definition layer PDL on the base substrate BS; and an orthographic projection of the second sub-layer BM2-2 of the second black matrix BM2 on the base substrate BS at least partially overlaps with an orthographic projection of the pixel definition layer PDL on the base substrate BS.

In some embodiments, in the portion of the display panel having the plurality of second pixels, a portion of the first black matrix BM1 between two adjacent subpixels has a third width w3 along a plane intersecting the two adjacent subpixels and the portion of the first black matrix BM1 and perpendicular to a surface of the base substrate BS, a portion of the first sub-layer BM2-1 of the second black matrix BM2 between the same two adjacent subpixels has a fourth width w4 along a plane intersecting the two adjacent subpixels and the portion of the first sub-layer BM2-1 and perpendicular to a surface of the base substrate BS, a portion of the second sub-layer BM2-2 of the second black matrix BM2 between the same two adjacent subpixels has the fourth width w4 along a plane intersecting the two adjacent subpixels and the portion of the second sub-layer BM2-2 and perpendicular to a surface of the base substrate BS, a portion of the pixel definition layer PDL between the same two adjacent subpixels has a fifth width w5 along a plane intersecting the two adjacent subpixels and the portion of the pixel definition layer PDL and perpendicular to the surface of the base substrate BS.

Optionally, the third width w3 is substantially the same as the fifth width w5.

Optionally, the fourth width w4 is substantially the same as the fifth width w5.

Optionally, the third width w3 is substantially the same as the fourth width w4.

Optionally, the third width w3, the fourth width w4, and the fifth width w5 are substantially the same.

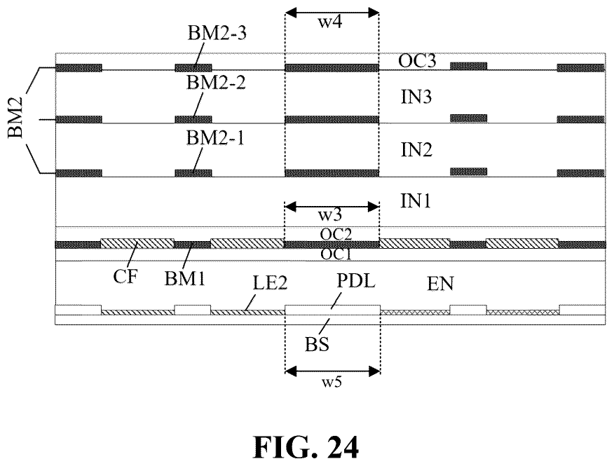

FIG. 24 is a cross-sectional view of a plurality of second pixels in a portion of a display panel in alternative embodiments according to the present disclosure. Referring to FIG. 24, the second black matrix BM2 in some embodiments includes multiple sub-layers, e.g., a first sub-layer BM2-1, a second sub-layer BM2-2, and a third sub-layer BM2-3. In some embodiments, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; a first insulating layer IN1 on a side of the second overcoat layer OC2 away from the base substrate BS; a first sub-layer BM2-1 of a second black matrix BM2 on a side of the first insulating layer IN1 away from the base substrate BS; a second insulating layer IN2 on a side of the first sub-layer BM2-1 of the second black matrix BM2 away from the base substrate BS; a second sub-layer BM2-2 of the second black matrix BM2 on a side of the second insulating layer IN2 away from the base substrate BS; a third insulating layer IN3 on a side of the second sub-layer BM2-2 of the second black matrix BM2 away from the base substrate BS; a third sub-layer BM2-3 of the second black matrix BM2 on a side of the third insulating layer IN3 away from the base substrate BS; and a third overcoat layer OC3 on a side of the third sub-layer BM2-3 of the second black matrix BM2 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In one example, the encapsulating layer EN has a thickness in a range of 8 μm to 20 μm. In another example, the first overcoat layer OC1 has a thickness in a range of 2 μm to 5 μm. In another example, the second overcoat layer OC2 has a thickness in a range of 3 μm to 8 μm. In another example, the first insulating layer IN1, the second insulating layer IN2, and the third insulating layer have a combined thickness in a range of 10 μm to 40 μm. In another example, the third overcoat layer OC3 has a thickness in a range of 2 μm to 4 μm. In another example, two adjacent sub-layers of the second black matrix BM2 are spaced apart by a distance in a range of 5 μm to 15 μm.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; an orthographic projection of the first sub-layer BM2-1 of the second black matrix BM2 on the base substrate BS at least partially overlaps with an orthographic projection of the pixel definition layer PDL on the base substrate BS; an orthographic projection of the second sub-layer BM2-2 of the second black matrix BM2 on the base substrate BS at least partially overlaps with an orthographic projection of the pixel definition layer PDL on the base substrate BS; and an orthographic projection of the third sub-layer BM2-3 of the second black matrix BM2 on the base substrate BS at least partially overlaps with an orthographic projection of the pixel definition layer PDL on the base substrate BS.

In some embodiments, in the portion of the display panel having the plurality of second pixels, a portion of the first black matrix BM1 between two adjacent subpixels has a third width w3 along a plane intersecting the two adjacent subpixels and the portion of the first black matrix BM1 and perpendicular to a surface of the base substrate BS, a portion of the first sub-layer BM2-1 of the second black matrix BM2 between the same two adjacent subpixels has a fourth width w4 along a plane intersecting the two adjacent subpixels and the portion of the first sub-layer BM2-1 and perpendicular to a surface of the base substrate BS, a portion of the second sub-layer BM2-2 of the second black matrix BM2 between the same two adjacent subpixels has the fourth width w4 along a plane intersecting the two adjacent subpixels and the portion of the second sub-layer BM2-2 and perpendicular to a surface of the base substrate BS, a portion of the third sub-layer BM2-3 of the second black matrix BM2 between the same two adjacent subpixels has the fourth width w4 along a plane intersecting the two adjacent subpixels and the portion of the third sub-layer BM2-3 and perpendicular to a surface of the base substrate BS, a portion of the pixel definition layer PDL between the same two adjacent subpixels has a fifth width w5 along a plane intersecting the two adjacent subpixels and the portion of the pixel definition layer PDL and perpendicular to the surface of the base substrate BS.

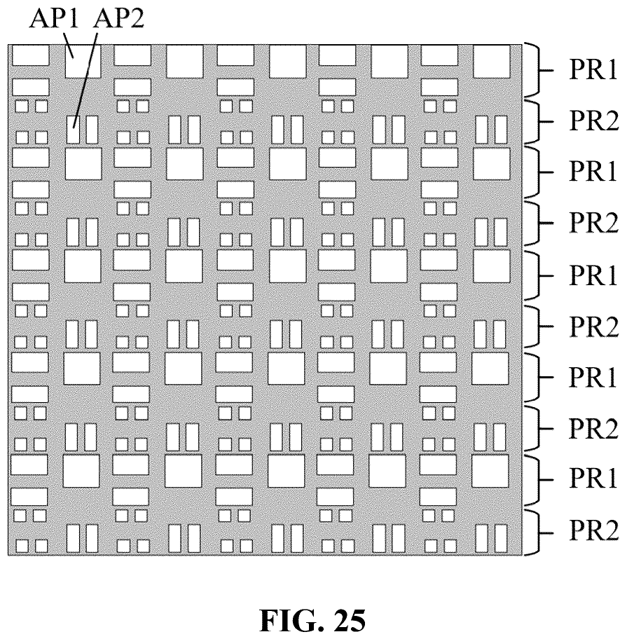

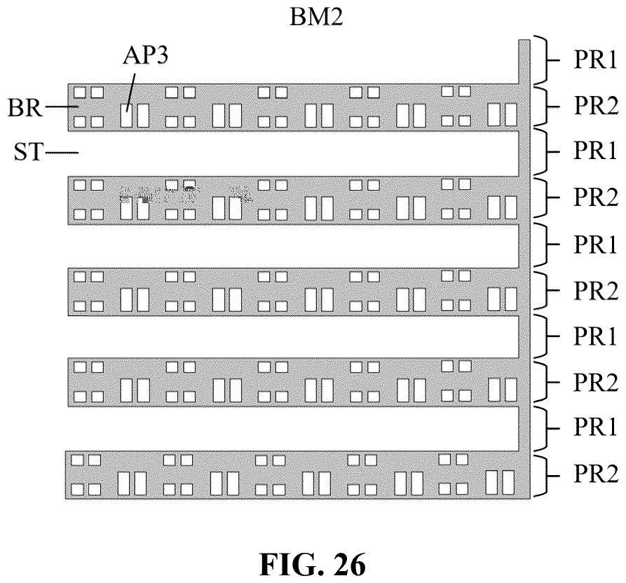

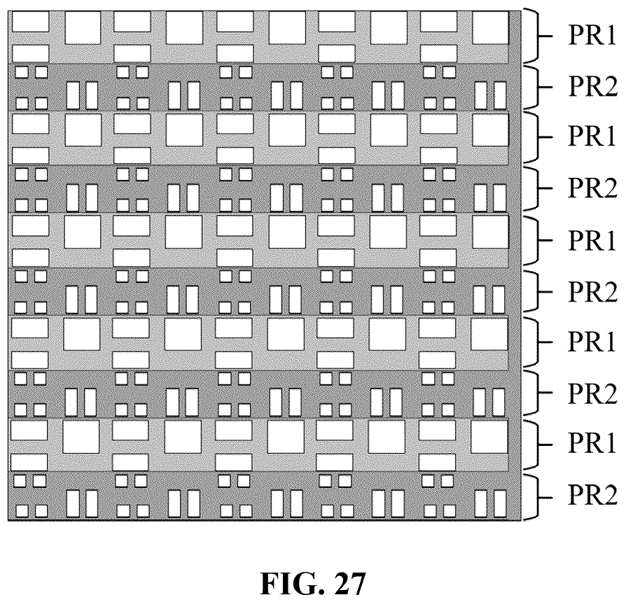

FIG. 25 is a plan view of a first black matrix in some embodiments according to the present disclosure. FIG. 26 is a plan view of a second black matrix in some embodiments according to the present disclosure. FIG. 27 is a superimposition of a first black matrix and a second black matrix in some embodiments according to the present disclosure. The second black matrix BM2 depicted in FIG. 26 and FIG. 27 may include multiple sub-layers (e.g., two sub-layers as shown in FIG. 23, or three sub-layers as shown in FIG. 24). Referring to FIG. 25 to FIG. 27, the first black matrix BM1 is at least partially present in regions corresponding to the plurality of first pixel rows PR1 and a plurality of second pixel rows PR2, whereas the second black matrix BM2 is at least partially absent in regions corresponding to the plurality of first pixel rows PR1, and at least partially present in regions corresponding to the plurality of second pixel rows PR2.

In some embodiments, the regions corresponding to the plurality of first pixel rows PR1 is substantially absent (e.g., at least 50% absent, at least 55% absent, at least 60% absent, at least 65% absent, at least 70% absent, at least 75% absent, at least 80% absent, at least 85% absent, at least 90% absent, at least 95% absent, at least 99% absent, or completely absent) of any sub-layer of the second black matrix BM2.

In some embodiments, in regions corresponding to the plurality of first pixel rows PR1, an orthographic projection of the first black matrix BM1 on a base substrate is substantially non-overlapping (e.g., at least 50% non-overlapping, at least 55% non-overlapping, at least 60% non-overlapping, at least 65% non-overlapping, at least 70% non-overlapping, at least 75% non-overlapping, at least 80% non-overlapping, at least 85% non-overlapping, at least 90% non-overlapping, at least 95% non-overlapping, at least 99% non-overlapping, completely non-overlapping,) with an orthographic projection of any sub-layer of the second black matrix BM2 on the base substrate.

In some embodiments, in regions corresponding to the plurality of second pixel rows PR2, the orthographic projection of the first black matrix BM1 on the base substrate at least partially (e.g., at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 99%) overlaps with the orthographic projection of at least a sub-layer of the second black matrix BM2 on the base substrate.

In some embodiments, a respective sub-layer of the second black matrix BM2 includes a plurality of bars BR, and the display panel includes a plurality of slits ST, the plurality of bars BR and the plurality of slits ST are alternately arranged. Two adjacent bars of the plurality of bars BR are spaced apart by a slit of the plurality of slits ST. Two adjacent slits of the plurality of slits ST are spaced apart by a bar of the plurality of bars BR. The plurality of bars BR correspond to the plurality of second pixel rows PR2. The plurality of slits ST correspond to the plurality of first pixel rows PR1.

In some embodiments, the display panel includes a plurality of first apertures AP1 extending through the first black matrix BM1, and a plurality of second apertures AP2 extending through the first black matrix BM1, The plurality of first apertures AP1 are configured to allow light emitted from a plurality of first light emitting elements in the plurality of first subpixels to transmit through, the plurality of second apertures AP2 are configured to allow light emitted from a plurality of second light emitting elements in the plurality of second subpixels to transmit through.

In some embodiments, the display panel includes a plurality of third apertures AP3 extending through at least a sub-layer of the second black matrix BM2. The plurality of third apertures AP3 are configured to allow light emitted from a plurality of second light emitting elements in the plurality of second subpixels to transmit through.

In some embodiments, in the portion of the display panel having the plurality of second pixels, a second aperture of the plurality of second apertures AP2 configured to allow light emitted from a second light emitting element to transmit through has a first aperture width along a plane intersecting the two adjacent second subpixels and perpendicular to a surface of the base substrate, a third aperture of the plurality of third apertures AP3 configured to allow light emitted from a same second light emitting element to transmit through has a second aperture width along the plane intersecting the two adjacent second subpixels and perpendicular to the surface of the base substrate. Optionally, the first aperture width and the second aperture width are substantially the same.

In some embodiments, an orthographic projection of an edge of a second aperture of the plurality of second apertures AP2 configured to allow light emitted from a second light emitting element to transmit through on a base substrate and an orthographic projection of an edge of a third aperture of the plurality of third apertures AP3 configured to allow light emitted from a same second light emitting element to transmit through on the base substrate substantially (e.g., at least 50%, at least 55%, at least 60%, at least 65%, at least 70%, at least 75%, at least 80%, at least 85%, at least 90%, at least 95%, at least 99%, or completely) overlap with each other.

The inventors of the present disclosure discover that, when the display panel is operated in the second mode, the display panel having the structure according to the present disclosure can effectively reduce the anti-peeping viewing angle. In one example, the left and right sides' 45° Luminance Decay ratio in the display panel according to the present disclosure can be reduced to less than 0.5%, and the upper side's 45° Luminance Decay ratio in the display panel according to the present disclosure can be reduced to less than 0.5%.

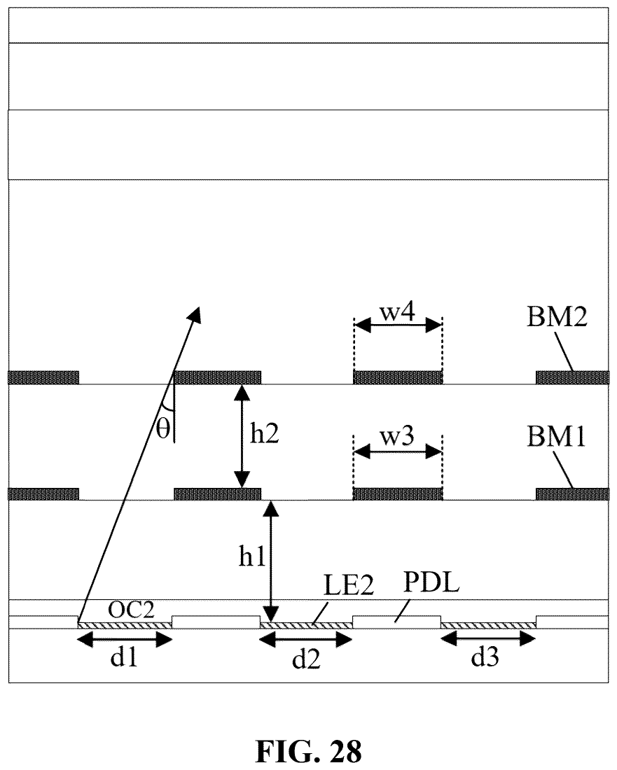

FIG. 28 illustrates various parameters in a display panel in some embodiments according to the present disclosure. Referring to FIG. 28, a portion of the first black matrix BM1 between two adjacent subpixels has a third width w3 along a plane intersecting the two adjacent subpixels and the portion of the first black matrix BM1 and perpendicular to a surface of the base substrate, a portion of the second black matrix BM2 between the same two adjacent subpixels has a fourth width w4 along a plane intersecting the two adjacent subpixels and the portion of the second black matrix BM2 and perpendicular to a surface of the base substrate. A first subpixel has a first subpixel width d1 along a plane intersecting the two adjacent subpixels and the portion of the pixel definition layer PDL and perpendicular to a surface of the base substrate. A second subpixel has a second subpixel width d2 along the plane intersecting the two adjacent subpixels and the portion of the pixel definition layer PDL and perpendicular to a surface of the base substrate. A third subpixel has a third subpixel width d3 along the plane intersecting the two adjacent subpixels and the portion of the pixel definition layer PDL and perpendicular to a surface of the base substrate BS. The first black matrix BM1 is spaced apart from a respective subpixel by a distance h1. The second black matrix BM2 is spaced apart from the first black matrix BM1 by a distance h2. An emission angle θ of the respective subpixel satisfies the following condition: arctan θ is in a range of d/((h1+h2)−0.1*(h)+h2)) to d/((h1+h2)+0.1*(h1+h2)), wherein d is a subpixel width of the respective subpixel along the plane intersecting the two adjacent subpixels and the portion of the pixel definition layer PDL and perpendicular to a surface of the base substrate.

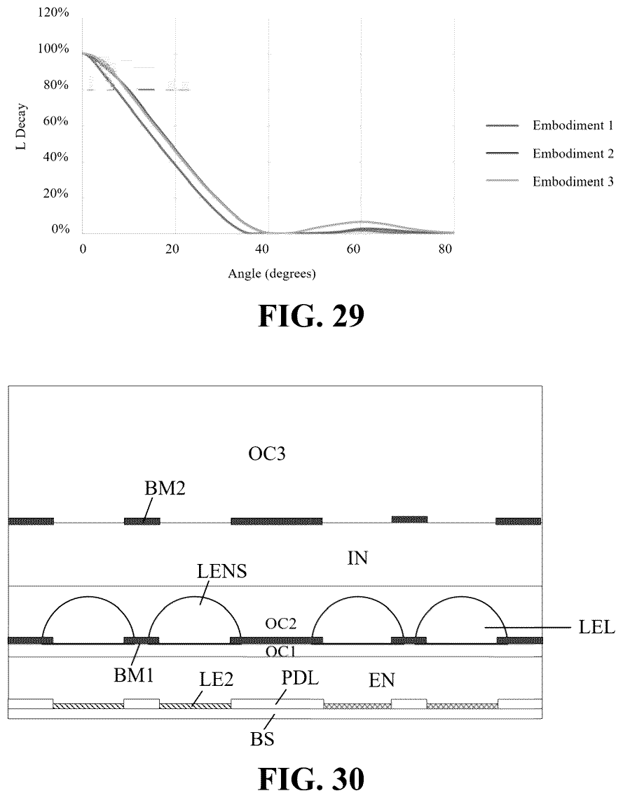

FIG. 29 shows a correlation between luminance decay and a viewing angle in several embodiments according to the present disclosure. As shown in FIG. 29, the luminance decay is reduced to nearly zero when the viewing angle increases from 0 degree to 40 degrees, In Embodiment 1, d1=d2=d3=9.5 μm; w3=w4=7 μm; h1=12 μm; h2=11 μm; and θ is 22.4 degrees. In Embodiment 2, d1=d2=d3=9.5 μm; w3=7 μm; w4=5 μm; h1=12 μm; h2=11 μm; and θ is 24.5 degrees. In Embodiment 3, d1=d2=d3=9.5 μm; w3=5 μm; w4=5 μm; h1=12 μm; h2=11 μm; and θ is 24.5 degrees.

In some embodiments, the display panel further includes a lens layer having a plurality of lenses. Various appropriate implementations may be practiced in the present disclosure. FIG. 30 is a cross-sectional view of a plurality of second pixels in a portion of a display panel in some embodiments according to the present disclosure. Referring to FIG. 30, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a lens layer LEL and a first black matrix BM1 on a side of the first overcoat layer OC1 away from the base substrate BS; a second overcoat layer OC2 on a side of the lens layer LEL and the first black matrix BM1 away from the base substrate BS; an insulating layer IN on a side of the second overcoat layer OC2 away from the base substrate BS; a second black matrix BM2 on a side of the insulating layer IN away from the base substrate BS; and a third overcoat layer OC3 on a side of the second black matrix BM2 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; and an orthographic projection of the second black matrix BM2 on the base substrate BS at least partially overlaps with an orthographic projection of the pixel definition layer PDL on the base substrate BS.

In some embodiments, the lens layer LEL includes a plurality of lenses LENS, In some embodiments, in the portion of the display panel having the plurality of second pixels, an orthographic projection of a respective lens of the plurality of lenses LENS on the base substrate BS at least partially overlaps with an orthographic projection of the second light emitting element LE2 on the base substrate. The inventors of the present disclosure discover that, by having the lens layer LEL, the luminance decay can be further reduced.

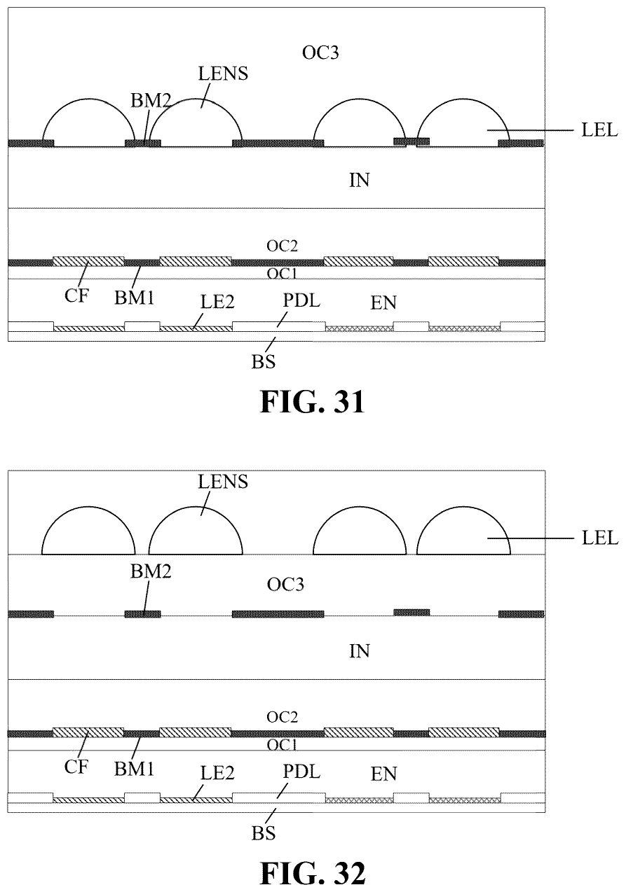

FIG. 31 is a cross-sectional view of a plurality of second pixels in a portion of a display panel in some embodiments according to the present disclosure. Referring to FIG. 31, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; an insulating layer IN on a side of the second overcoat layer OC2 away from the base substrate BS; a lens layer LEL and a second black matrix BM2 on a side of the insulating layer IN away from the base substrate BS; and a third overcoat layer OC3 on a side of the lens layer LEL and the second black matrix BM2 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; and an orthographic projection of the second black matrix BM2 on the base substrate BS at least partially overlaps with an orthographic projection of the pixel definition layer PDL on the base substrate BS.

In some embodiments, the lens layer LEL includes a plurality of lenses LENS. In some embodiments, in the portion of the display panel having the plurality of second pixels, an orthographic projection of a respective lens of the plurality of lenses LENS on the base substrate BS at least partially overlaps with an orthographic projection of the second light emitting element LE2 on the base substrate. The inventors of the present disclosure discover that, by having the lens layer LEL, the luminance decay can be further reduced.

FIG. 32 is a cross-sectional view of a plurality of second pixels in a portion of a display panel in some embodiments according to the present disclosure. Referring to FIG. 32, the portion of the display panel having the plurality of second pixels includes a base substrate BS; a pixel definition layer PDL on the base substrate BS, and defining a plurality of second subpixel apertures, a plurality of second light emitting elements LE2 at least partially received in the plurality of second subpixel apertures; an encapsulating layer EN on a side of the pixel definition layer PDL and the plurality of second light emitting elements LE2 away from the base substrate BS; a first overcoat layer OC1 on a side of the encapsulating layer EN away from the base substrate BS; a color filter CF and a first black matrix BM1 on a side of the first overcoat layer OC1 away from the base substrate BS; a second overcoat layer OC2 on a side of the color filter CF and the first black matrix BM1 away from the base substrate BS; an insulating layer IN on a side of the second overcoat layer OC2 away from the base substrate BS; a second black matrix BM2 on a side of the insulating layer IN away from the base substrate BS; a third overcoat layer OC3 on a side of the second black matrix BM2 away from the base substrate BS; and a lens layer LEL on a side of the third overcoat layer OC3 away from the base substrate BS. Optionally, the first black matrix BM1 is a unitary structure extending in the portion of the display panel having the plurality of first pixels and the portion of the display panel having the plurality of second pixels. Optionally, the portion of the display panel further includes a touch structure on a side of the encapsulating layer EN away from the base substrate BS and on a side of the first overcoat layer OC1 closer to the base substrate BS.

In some embodiments, in the portion of the display panel having the plurality of second pixels, an orthographic projection of the first black matrix BM1 on the base substrate BS at least partially overlaps with an orthographic projection of the pixel definition layer PDL on the base substrate BS; and an orthographic projection of the second black matrix BM2 on the base substrate BS at least partially overlaps with an orthographic projection of the pixel definition layer PDL on the base substrate BS.

In some embodiments, the lens layer LEL includes a plurality of lenses LENS. In some embodiments, in the portion of the display panel having the plurality of second pixels, an orthographic projection of a respective lens of the plurality of lenses LENS on the base substrate BS at least partially overlaps with an orthographic projection of the second light emitting element LE2 on the base substrate. The inventors of the present disclosure discover that, by having the lens layer LEL, the luminance decay can be further reduced.

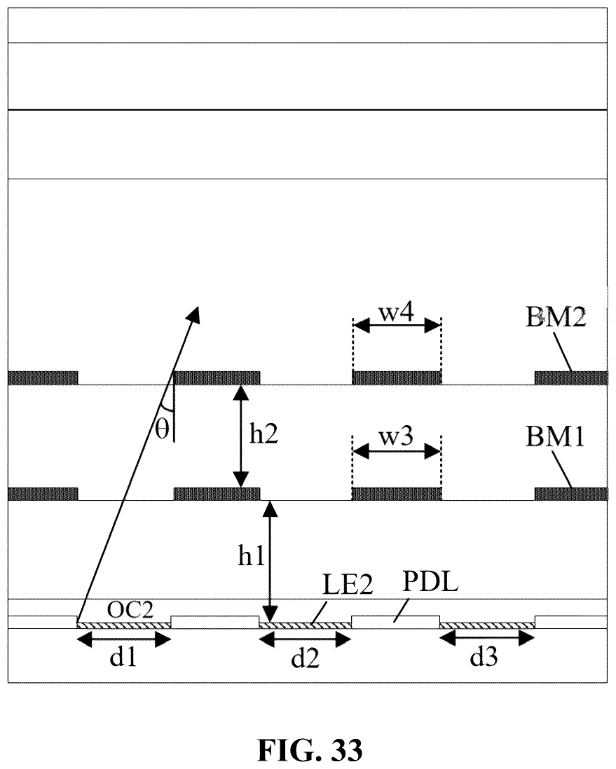

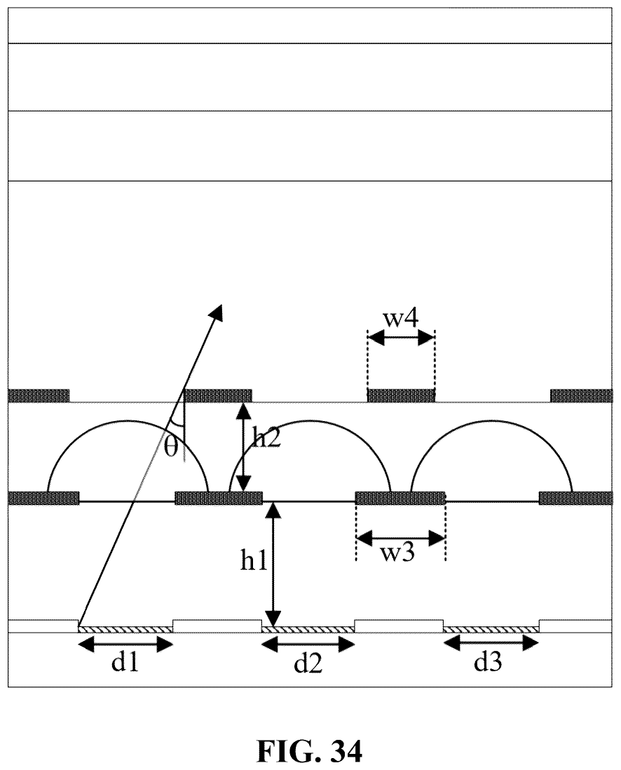

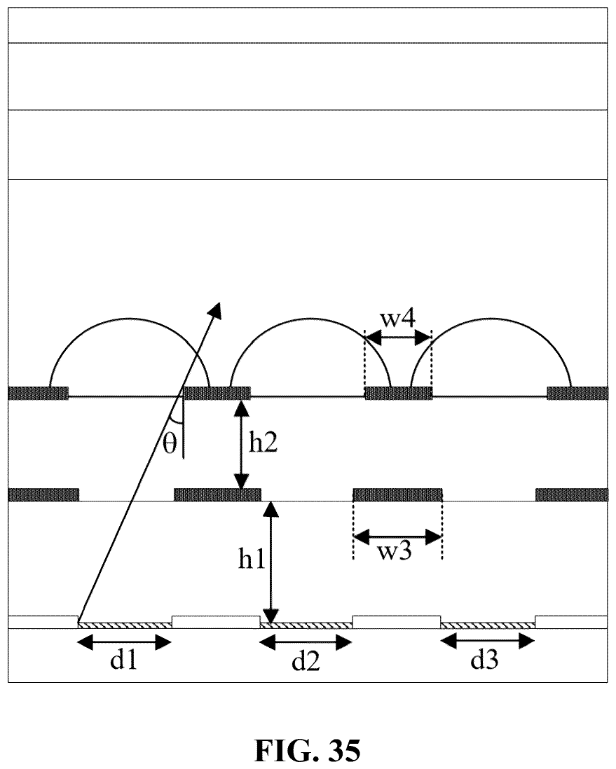

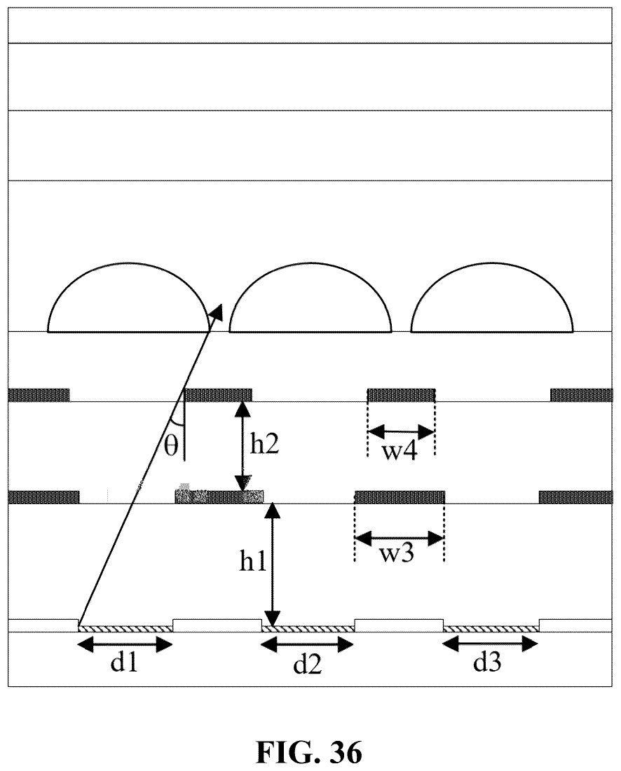

FIG. 33 illustrates various parameters in a display panel in some embodiments according to the present disclosure. FIG. 34 illustrates various parameters in a display panel in some embodiments according to the present disclosure. FIG. 35 illustrates various parameters in a display panel in some embodiments according to the present disclosure. FIG. 36 illustrates various parameters in a display panel in some embodiments according to the present disclosure. Referring to FIG. 33 to FIG. 36, a portion of the first black matrix BM1 between two adjacent subpixels has a third width w3 along a plane intersecting the two adjacent subpixels and the portion of the first black matrix BM1 and perpendicular to a surface of the base substrate, a portion of the second black matrix BM2 between the same two adjacent subpixels has a fourth width w4 along a plane intersecting the two adjacent subpixels and the portion of the second black matrix BM2 and perpendicular to a surface of the base substrate. A first subpixel has a first subpixel width d1 along a plane intersecting the two adjacent subpixels and the portion of the pixel definition layer PDL and perpendicular to a surface of the base substrate. A second subpixel has a second subpixel width d2 along the plane intersecting the two adjacent subpixels and the portion of the pixel definition layer PDL and perpendicular to a surface of the base substrate. A third subpixel has a third subpixel width d3 along the plane intersecting the two adjacent subpixels and the portion of the pixel definition layer PDL and perpendicular to a surface of the base substrate BS. The first black matrix BM1 is spaced apart from a respective subpixel by a distance h1. The second black matrix BM2 is spaced apart from the first black matrix BM1 by a distance h2. An emission angle 0 of the respective subpixel satisfies arctan θ=d/(h1+h2), wherein d is a subpixel width of the respective subpixel along the plane intersecting the two adjacent subpixels and the portion of the pixel definition layer PDL and perpendicular to a surface of the base substrate. The display panel depicted in FIG. 33 does not include a lens layer. The display panels depicted in FIG. 34 to FIG. 36 include a lens layer.

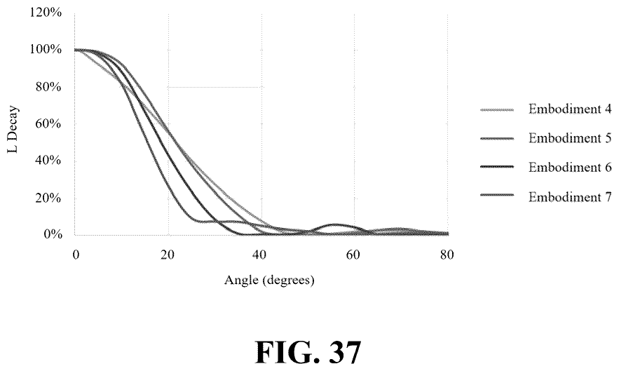

FIG. 37 shows a correlation between luminance decay and a viewing angle in several embodiments according to the present disclosure. In Embodiment 4, d1=d2=d3=9.5 μm; w3=7 μm; w4=5 μm; h1=12 μm; h2=7 μm; and θ is 28.9 degrees. As shown in the Embodiment 4, the luminance decay is reduced to nearly zero when the viewing angle increases from 0 degree to 40 degrees.

In Embodiment 5, d1=d2=d3=9.5 μm; w3=7 μm; w4=5 μm; h1=12 μm; h2=7 μm; and θ is 28.9 degrees. A bottom surface of a respective lens of the plurality of lenses has a diameter of 14.3 μm. A pitch of the plurality of lenses is 2.2 μm. A height of the respective lens is 5 μm. A refractive index of the respective lens is 1.7. A refractive index of the one or more insulating layer in direct contact with the respective lens is 1.53.

In Embodiment 6, d1=d2=d3=9.5 μm; w3=5 μm; w4=5 μm; h1=12 μm; h2=11 μm; and θ is 24.5 degrees. A bottom surface of a respective lens of the plurality of lenses has a diameter of 14.3 μm. A pitch of the plurality of lenses is 2.2 μm. A height of the respective lens is 5 μm. A refractive index of the respective lens is 1.7. A refractive index of the one or more insulating layer in direct contact with the respective lens is 1.53.

In Embodiment 7, d1=d2=d3=9.5 μm; w3=5 μm; w4=5 μm; h1=12 μm; h2=11 μm; and θ is 24.5 degrees. A bottom surface of a respective lens of the plurality of lenses has a diameter of 14.3 μm. A pitch of the plurality of lenses is 2.2 μm. A height of the respective lens is 5 μm. A refractive index of the respective lens is 1.7. A refractive index of the one or more insulating layer in direct contact with the respective lens is 1.53.

As shown in the Embodiments 5 to 7, the luminance decay is reduced to nearly zero when the viewing angle increases from 0 degree to an angle less than 40 degrees (e.g., 25 degrees to 40 degrees).

In another aspect, the present disclosure provides a display apparatus including the display panel described herein, and one or more integrated circuits connected to the display: panel. Examples of appropriate display apparatuses include, but are not limited to, an electronic paper, a mobile phone, a tablet computer, a television, a monitor, a notebook computer, a digital album, a GPS, etc.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention” “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display panel, comprising a plurality of first pixels; a plurality of second pixels; a first black matrix; and a second black matrix;
wherein the first black matrix is at least partially present in regions having the plurality of first pixels and regions having the plurality of second pixels; and
the second black matrix is at least partially present in the regions having the plurality of second pixels, and at least partially absent in the regions having the plurality of first pixels.

2. The display panel of claim 1, wherein the regions having the plurality of first pixels is substantially absent of the second black matrix;
in the regions having the plurality of first pixels, an orthographic projection of the first black matrix on a base substrate is substantially non-overlapping with an orthographic projection of the second black matrix on the base substrate; and
in the regions having the plurality of second pixels, the orthographic projection of the first black matrix on the base substrate at least partially overlaps with the orthographic projection of the second black matrix on the base substrate.

3. The display panel of claim 1, wherein the second black matrix comprises a plurality of bars;
the display panel comprises a plurality of slits;
the plurality of bars and the plurality of slits are alternately arranged;
two adjacent bars of the plurality of bars are spaced apart by a slit of the plurality of slits; and
two adjacent slits of the plurality of slits are spaced apart by a bar of the plurality of bars.

4. The display panel of claim 1, further comprising a pixel definition layer defining a plurality of first subpixel apertures in the regions having the plurality of first pixels and a plurality of second subpixel apertures in the regions having the plurality of second pixels;
wherein, in the regions having the plurality of first pixels, a portion of the first black matrix between two adjacent subpixels has a first width along a plane intersecting the two adjacent subpixels and the portion of the first black matrix and perpendicular to a surface of the base substrate, a portion of the pixel definition layer between the same two adjacent subpixels has a second width along a plane intersecting the two adjacent subpixels and the portion of the pixel definition layer and perpendicular to the surface of the base substrate, the second width being greater than the first width; and
in the regions having the plurality of second pixels, a portion of the first black matrix between two adjacent subpixels has a third width along a plane intersecting the two adjacent subpixels and the portion of the first black matrix and perpendicular to a surface of the base substrate, a portion of the pixel definition layer between the same two adjacent subpixels has a fifth width along a plane intersecting the two adjacent subpixels and the portion of the pixel definition layer and perpendicular to the surface of the base substrate, the third width being substantially the same as the fifth width.

5. The display panel of claim 4, wherein, in the regions having the plurality of second pixels, a portion of the second black matrix between the same two adjacent subpixels has a fourth width along a plane intersecting the two adjacent subpixels and the portion of the second black matrix and perpendicular to the surface of the base substrate; and
the fourth width is greater than the fifth width.

6. The display panel of claim 4, wherein, in the regions having the plurality of second pixels, a portion of the second black matrix between the same two adjacent subpixels has a fourth width along a plane intersecting the two adjacent subpixels and the portion of the second black matrix and perpendicular to the surface of the base substrate; and
the fourth width is substantially the same as the fifth width.

7. The display panel of claim 1, comprising:
a plurality of first apertures extending through the first black matrix;
a plurality of second apertures extending through the first black matrix; and
a plurality of third apertures extending through the second black matrix;
the plurality of first apertures are configured to allow light emitted from a plurality of first light emitting elements in a plurality of first subpixels to transmit through;
the plurality of second apertures are configured to allow light emitted from a plurality of second light emitting elements in a plurality of second subpixels to transmit through; and
the plurality of third apertures are configured to allow light emitted from a plurality of second light emitting elements in the plurality of second subpixels to transmit through;
wherein, in the portion of the display panel having the plurality of second pixels, a second aperture of the plurality of second apertures configured to allow light emitted from a second light emitting element to transmit through has a first aperture width along a plane intersecting two adjacent second subpixels and perpendicular to a surface of the base substrate, and a third aperture of the plurality of third apertures configured to allow light emitted from a same second light emitting element to transmit through has a second aperture width along the plane intersecting the two adjacent second subpixels and perpendicular to the surface of the base substrate.

8. The display panel of claim 7, wherein the first aperture width is greater than the second aperture width.

9. The display panel of claim 7, wherein an orthographic projection of an edge of the second aperture on a base substrate substantially surrounds an orthographic projection of an edge of the third aperture on the base substrate.

10. The display panel of claim 7, wherein the first aperture width and the second aperture width are substantially the same.

11. The display panel of claim 7, wherein an orthographic projection of an edge of the second aperture on a base substrate and an orthographic projection of an edge of the third aperture on the base substrate substantially overlap with each other.

12. The display panel of claim 1, wherein, in the regions having the plurality of second pixels, further comprising:
an insulating layer spacing apart the first black matrix and the second black matrix; and
a light control structure at least partially extending through the insulating layer;
wherein the light control structure is connected to a portion of the first black matrix, and is connected to a portion of the second black matrix.

13. The display panel of claim 1, wherein the second black matrix comprises multiple sub-layers;
two adjacent sub-layers of the multiple sub-layers are spaced apart by an insulating layer; and
orthographic projections of the multiple sub-layers on a base substrate substantially overlap with each other.

14. The display panel of claim 1, further comprising a lens layer comprising a plurality of lenses;
wherein, in the regions having the plurality of second pixels, an orthographic projection of a respective lens of the plurality of lenses on the base substrate at least partially overlaps with an orthographic projection of a second light emitting element on the base substrate.

15. The display panel of claim 14, comprising:
a first overcoat layer;
the plurality of lenses and the first black matrix on the first overcoat layer;
a second overcoat layer on a side of the plurality of lenses and the first black matrix away from the first overcoat layer; and
the second black matrix on a side of the second overcoat layer away from the plurality of lenses and the first black matrix.

16. The display panel of claim 14, comprising:
a first overcoat layer;
the first black matrix on the first overcoat layer;
a second overcoat layer on a side of the first black matrix away from the first overcoat layer; and
the plurality of lenses and the second black matrix on a side of the second overcoat layer away from the first black matrix.

17. The display panel of claim 14, comprising:
a first overcoat layer;
the first black matrix on the first overcoat layer;
a second overcoat layer on a side of the first black matrix away from the first overcoat layer; and
the second black matrix on a side of the second overcoat layer away from the first black matrix;
a third overcoat layer on a side of the second black matrix away from the second overcoat layer; and
the plurality of lenses on a side of the third overcoat layer away from the second black matrix.

18. The display panel of claim 1, comprising a plurality of first pixel rows and a plurality of second pixel rows alternately arranged;
two adjacent first pixel rows of the plurality of first pixel rows are spaced apart by an individual second pixel row of the plurality of second pixel rows;
two adjacent second pixel rows of the plurality of second pixel rows are spaced apart by an individual first pixel row of the plurality of first pixel rows;
a respective first pixel row of the plurality of first pixel rows comprises multiple pixels of the plurality of first pixels;
a respective second pixel row of the plurality of second pixel rows comprises multiple second pixels of the plurality of second pixels;
a respective first pixel of the plurality of first pixels comprises a first subpixel, a second subpixel, and a third subpixel; and
a respective second pixel of the plurality of second pixels comprises multiple fourth subpixels, multiple fifth subpixels, and multiple sixth subpixels.

19. A display panel, comprising a plurality of first pixels; a plurality of second pixels; a first black matrix; and a second black matrix;
wherein, in regions having the plurality of first pixels, an orthographic projection of the first black matrix on a base substrate is substantially non-overlapping with an orthographic projection of the second black matrix on the base substrate; and
in regions having the plurality of second pixels, the orthographic projection of the first black matrix on the base substrate at least partially overlaps with the orthographic projection of the second black matrix on the base substrate.

20. A display apparatus, comprising the display panel of claim 1, and one or more integrated circuits connected to the display panel.
